(19) United States
(12) Patent Application Publication
(10) Pub. No.: US 2026/0304952 A1
(43) Pub. Date: Oct. 1, 2026

(54) INTEGRATED CIRCUIT DEVICE

(71) Applicant: Samsung Electronics Co., Ltd., Suwon-si (KR)

(72) Inventors: Jisoo Park, Suwon-si (KR); Byungsung Kim, Suwon-si (KR); Panjae Park, Suwon-si (KR); Junghan Lee, Suwon-si (KR); Kwanyoung Chun, Suwon-si (KR)

(73) Assignee: Samsung Electronics Co., Ltd., Suwon-si (KR)

(21) Appl. No.: 19/577,818

(22) Filed: Mar. 25, 2026

(30) Foreign Application Priority Data
Mar. 27, 2025 (KR) 10-2025-0039699

(51) Int. Cl. H10D 84/90; H10D 89/10

(52) U.S. Cl. CPC H10D 84/922; H10D 84/931; H10D 84/953; H10D 84/981; H10D 89/10

(57) ABSTRACT

Provided is an integrated circuit device include a first logic cell region and a second logic cell region adjacent to one another in a first horizontal direction, a plurality of first logic cells arranged in portions of the first logic cell region and the second logic cell region, each of the plurality of first logic cells having a first cell height, and at least one second logic cell arranged in the other portion of the second logic cell region and having a second cell height greater than the first cell height.

### CROSS-REFERENCE TO RELATED APPLICATIONS

This present application claims priority to and the benefit under 35 U.S.C. § 119(a)-(d) to Korean Patent Application No. 10-2025-0039699, filed on Mar. 27, 2025, in the Korean Intellectual Property office, the entire disclosure of which is incorporated herein by reference.

### FIELD

The disclosed concepts relate to an integrated circuit device, and more particularly, to an integrated circuit device including standard cells having different channel widths.

### BACKGROUND

As the degree of integration of integrated circuit devices is increased, sizes thereof have been reduced to the extreme state and the scaling thereof has reached the limit. Accordingly, integrated circuit devices including standard cells having different channel widths for improving performance of the integrated circuit devices have been proposed.

### SUMMARY

The disclosed concepts provide an integrated circuit device including standard cells having different channel widths to improve operation reliability and the degree of integration thereof.

According to aspects of the disclosed concepts, there is provided an integrated circuit device including a first logic cell region and a second logic cell region adjacent to one another in a first horizontal direction, a plurality of first logic cells arranged in portions of the first logic cell region and the second logic cell region, each of the plurality of first logic cells having a first cell height, and at least one second logic cell arranged in the other portion of the second logic cell region and having a second cell height greater than the first cell height, wherein both ends of the at least one second logic cell in a second horizontal direction substantially orthogonal to the first horizontal direction are aligned, in the first horizontal direction, with one end of both ends in the second horizontal direction of one first logic cell arranged in the first logic cell region and the other end of both ends in the second horizontal direction of the other first logic cell among the plurality of first logic cells.

According to aspects of the disclosed concepts, there is provided an integrated circuit device including a first logic cell region and a second logic cell region adjacent to one another in a first horizontal direction, a plurality of first logic cells arranged in portions of the first logic cell region and the second logic cell region, each of the plurality of first logic cells having a first cell height, and at least one second logic cell arranged in the other portion of the second logic cell region and having a second cell height greater than the first cell height, wherein the first logic cells arranged in the first logic cell region among the plurality of first logic cells are arranged in a second horizontal direction substantially orthogonal to the first horizontal direction, wherein the first logic cells arranged in the second logic cell region among the plurality of first logic cells are arranged on both sides of the at least one second logic cell in the second horizontal direction, wherein each of the plurality of first logic cells includes a first n-channel field effect transistor (FET) (NFET) and a first p-channel FET (PFET), wherein the at least one second logic cell includes a second NFET and a second PFET, and wherein a channel width of each of the second NFET and the second PFET is greater than a channel width of each of the first NFET and the first PFET, and wherein both ends of the at least one second logic cell in a second horizontal direction are aligned, in the first horizontal direction, with one end of both ends in the second horizontal direction of one first logic cell arranged in the first logic cell region and the other end of both ends in the second horizontal direction of the other first logic cell among the plurality of first logic cells.

According to aspects of the disclosed concepts, there is provided an integrated circuit device including a first logic cell region and a second logic cell region adjacent to one another in a first horizontal direction, a plurality of gate electrodes configured to extend in the first logic cell region and the second logic cell region in a second horizontal direction substantially orthogonal to the first horizontal direction, a plurality of first logic cells arranged in portions of the first logic cell region and the second logic cell region, each of the plurality of first logic cells having a first cell height in the second horizontal direction, and at least one second logic cell arranged in the other portion of the second logic cell region and having a second cell height greater than the first cell height in the second horizontal direction, wherein the first logic cells arranged in the first logic cell region among the plurality of first logic cells are arranged in the second horizontal direction, wherein the first logic cells arranged in the second logic cell region among the plurality of first logic cells are arranged on both sides of the at least one second logic cell in the second horizontal direction, wherein each of the plurality of first logic cells includes a first nanosheet stacked structure including nanosheets arranged in portions overlapping any one of the plurality of gate electrodes in a vertical direction, sequentially apart from one another in the vertical direction, and having a first channel width, and a first source/drain region connected to the nanosheets included in the first nanosheet stacked structure, wherein at least one second logic cell includes a second nanosheet stacked structure including nanosheets arranged in portions overlapping any one of the plurality of gate electrodes in the vertical direction, sequentially apart from one another in the vertical direction, and having a second channel width greater than the first channel width, and a second source/drain region connected to the nanosheets included in the second nanosheet stacked structure, and wherein one end of both ends in the second horizontal direction of the at least one second logic cell is aligned in the first horizontal direction with one end of both ends in the second horizontal direction of one first logic cell arranged in the first logic cell region among the plurality of first logic cells, and the other end of the both ends in the second horizontal direction of the at least one second logic cell is aligned in the first horizontal direction with the other end of the both ends in the second horizontal direction of the other one first logic cell arranged in the first logic cell region among the plurality of first logic cells.

According to aspects of the disclosed concepts, there is provided a method of manufacturing an integrated circuit device including obtaining input data defining standard cells, arranging, among the standard cells, a plurality of first logic cells each having a first cell height and at least one second logic cell having a second cell height greater than the first cell height in a first logic cell region and a second logic cell region adjacent to one another in a first horizontal direction, respectively, and generating output data defining a layout including the arranged plurality of standard cells, wherein the arranging of the plurality of first logic cells and the at least one second logic cell in the first logic cell region and the second logic cell region includes arranging the at least one second logic cell in a portion of the second logic cell region and arranging some of the plurality of first logic cells in other portion of the second logic cell region, wherein the first logic cells arranged in the first logic cell region among the plurality of first logic cells are arranged in a second horizontal direction substantially orthogonal to the first horizontal direction, wherein the first logic cells arranged in the second logic cell region among the plurality of first logic cells are arranged on both sides of the at least one second logic cell in the second horizontal direction, wherein both ends in the second horizontal direction of the at least one second logic cell are aligned in the first horizontal direction with one end of both ends in the second horizontal direction of one first logic cell arranged in the first logic cell region among the plurality of first logic cells and the other end of the both ends in the second horizontal direction of another one first logic cell.

In embodiments, the arranging of the plurality of first logic cells and the at least one second logic cell in the first logic cell region and the second logic cell region may include arranging a plurality of gate electrodes extending in the second horizontal direction in the first logic cell region and the second logic cell region, respectively, wherein each of the plurality of first logic cells includes a first nanosheet stacked structure including nanosheets arranged in a portion overlapping in a vertical direction any one among the plurality of gate electrodes and sequentially apart from one another in the vertical direction, and a first source/drain region connected to the nanosheets included in the first nanosheet stacked structure, and wherein the at least one second logic cell includes a second nanosheet stacked structure including nanosheets arranged in a portion overlapping in the vertical direction any one among the plurality of gate electrodes and sequentially apart from one another in the vertical direction, and a second source/drain region connected to the nanosheets included in the second nanosheet stacked structure.

In embodiments, the arranging of the plurality of first logic cells and the plurality of second logic cells in the first logic cell region and the second logic cell region, respectively, may include arranging a separation structure between the first logic cells adjacent to one another in the second horizontal direction among the plurality of first logic cells.

In embodiments, the separation structure may be in contact with the nanosheets included in the first nanosheet stacked structure.

In embodiments, the separation structure may be apart from the nanosheets included in the first nanosheet stacked structure.

In embodiments, the arranging of the plurality of first logic cells and the at least one second logic cells in the first logic cell region and the second logic cell region, respectively, may include arranging a plurality of backside power rails extending in the first horizontal direction, a plurality of backside power vias connected to at least one among the plurality of backside power rails, and a plurality of backside via contacts configured to connect the first source/drain region and the second source/drain region to the plurality of backside power vias.

In embodiments, one backside power via among the plurality of backside power vias may be connected to a backside via contact connected to the first source/drain region among the plurality of backside via contacts, the one backside power via may be connected to one backside power rail among the plurality of backside power rails, another backside power via among the plurality of backside power vias may be connected to the backside via contact connected to the second source/drain region among the plurality of backside via contacts, and the another backside power via may be connected to two backside power rails among the plurality of backside power rails.

In embodiments, the one of the two backside power rails among the plurality of backside power rails connected to the one backside power via may extend from the second logic cell region into the first logic cell region, and the another may not extend from the second logic cell region into the first logic cell region.

In embodiments, the nanosheets included in the first nanosheet stacked structure may have a first channel width, and the nanosheets included in the second nanosheet stacked structure may have a second channel width greater than the first channel width.

In embodiments, the arranging of the plurality of first logic cells and the at least one second logic cell in the first logic cell region and the second logic cell region, respectively, may include arranging a gate cut structure arranged between each of the first logic cells arranged in the second logic cell region among the plurality of first logic cells and the at least one second logic cell on both sides in the second horizontal direction of the at least one second logic cell, and apart from the nanosheets included in the second nanosheet stacked structure.

### BRIEF DESCRIPTION OF THE DRAWINGS

Embodiments of the inventive concept will be more clearly understood from the following detailed description taken in conjunction with the accompanying drawings in which:

FIG. 1 illustrates an integrated circuit device according to embodiments;

FIG. 2 is a diagram of a layout of an integrated circuit device according to embodiments;

FIG. 3 is a diagram of a layout of an integrated circuit device according to embodiments;

FIGS. 4A through 4D are cross-sectional views of layouts of an integrated circuit device, according to embodiments;

FIG. 5 is a diagram of a layout of an integrated circuit device according to embodiments;

FIGS. 6A through 6D are cross-sectional views of layouts of an integrated circuit device, according to embodiments;

FIG. 7 is a diagram of a layout of an integrated circuit device according to embodiments;

FIGS. 8A and 8B are diagrams of layouts of integrated circuit devices, respectively, according to embodiments;

FIGS. 9A and 9B are cross-sectional views of layouts of an integrated circuit device, according to embodiments;

FIG. 10 is a diagram of a layout of an integrated circuit device according to embodiments;

FIGS. 11A and 11B are cross-sectional views of layouts of an integrated circuit device, according to embodiments;

FIG. 12 is a flowchart of a method of manufacturing an integrated circuit device according to embodiments; and

FIG. 13 is a flowchart for describing operation S30 in FIG. 12 in detail.

### DETAILED DESCRIPTION

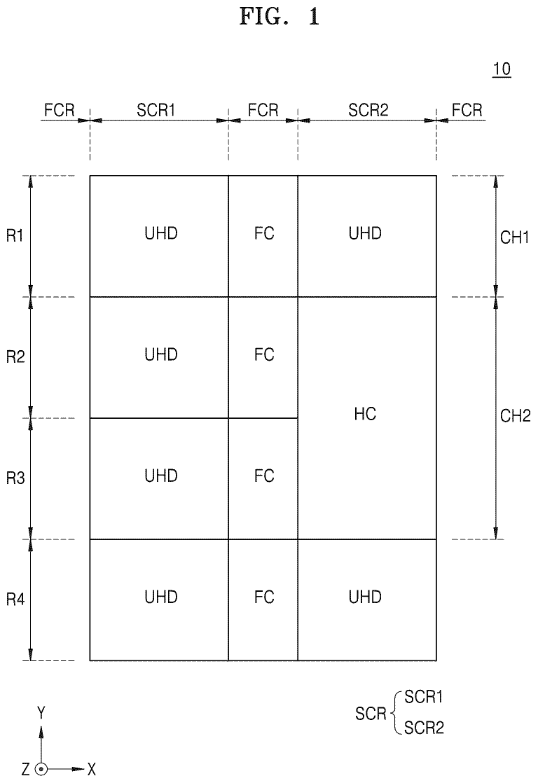

FIG. 1 illustrates an integrated circuit device 10 according to embodiments.

Referring to FIG. 1, the integrated circuit device 10 may include a plurality of logic cell regions SCR and a plurality of filler cell regions FCR arranged on an X-Y plane formed by a first horizontal direction (X direction) and a second horizontal direction (Y direction). The first horizontal direction (X direction) may be orthogonal to the second horizontal direction (Y direction). One of the filler cell region FCR may be arranged between a pair of the logic cell regions SCR adjacent to one another in the first horizontal direction (X direction). One of the logic cell region SCR may be arranged between a pair of the filler cell regions FCR adjacent to one another in the first horizontal direction (X direction). In some embodiments, the plurality of logic cell regions SCR and the plurality of filler cell regions FCR may be alternately arranged in the first horizontal direction (X direction), but are not limited thereto.

Standard cells may be arranged in the integrated circuit device 10. The standard cells may have a cell height in the second horizontal direction (Y direction) and may be arranged on first through fourth rows R1 through R4 extending in the first horizontal direction (X direction). The first through fourth rows R1 through R4 included in the integrated circuit device 10 may include the first row R1, the second row R2, the third row R3, and the fourth row R4. The standard cell may be a unit of a layout included in the integrated circuit device 10, and may be designed to perform a certain function. The standard cell may be referred to as a cell. In the specification, the cell height may be a height of the cell on a layout, that is, a plan layout, and may mean a horizontal width in the second horizontal direction (Y direction). In the specification, the standard cell may include a first logic cell UHD, a second logic cell HC, and a filler cell FC. The first logic cell UHD and the second logic cell HC may be arranged in the logic cell region SCR, and the filler cell FC may be arranged in the filler cell region FCR. The first logic cell UHD may be referred to as a basic cell or an ultra high-density (UHD) cell, and the second logic cell HC may be referred to as an expansion cell or a hybrid cell.

In the integrated circuit device 10, one contact poly pitch (CPP) may constitute the filler cell region FCR in the first horizontal direction (X direction), and two CPPs may constitute the logic cell region SCR in the first horizontal direction (X direction). For reference, the CPP may mean a pitch of gate electrodes in the first horizontal direction (X direction).

Each of the first logic cell UHD and the second logic cell HC may constitute the standard cell performing a logical function. In the specification, that each of the first logic cell UHD and the second logic cell HC constitutes an inverter (INV) is described as an example, but embodiments is not limited thereto. For example, each of the first logic cell UHD and the second logic cell HC may constitute the inverter (INV), AND, NAND, OR, NOR, exclusive OR (XOR), exclusive NOR (XNOR), an adder (ADD), a buffer (BUF), a delay (DLY), a filter (FIL), multiplexer (MXT/MXIT), OR/AND/INVERTER (OAI), AND/OR (AO), AND/OR/INVERTER (AOI), a D flip-flop, a reset flip-flop, a master-slave flip-flop, a latch, etc.

The first logic cell UHD may have a first cell height CH1 that is a horizontal width in the second horizontal direction (Y direction), and the second logic cell HC may have a second cell height CH2 that is a horizontal width in the second horizontal direction (Y direction). In some embodiments, the first logic cell UHD may include a standard cell having a minimum cell height among standard cells included in the integrated circuit device 10. For example, the first cell height CH1 may have a minimum value among cell heights of the standard cells included in the integrated circuit device 10. The second cell height CH2 may be greater than the first cell height CH1. For example, the second cell height CH2 may be an integer multiple of two or more times the first cell height CH1. In some embodiments, the second cell height CH2 may be twice the first cell height CH1.

The plurality of logic cell regions SCR may include a first logic cell region SCR1 and a second logic cell region SCR2 adjacent to the first logic cell region SCR1 in the first horizontal direction (X direction). In some embodiments, the filler cell region FCR may be arranged between the first logic cell region SCR1 and the second logic cell region SCR2. In the first logic cell region SCR1, one first logic cell UHD may be arranged on each of the first through fourth rows R1 through R4, and in the second logic cell region SCR2, one second logic cell HC may be arranged across two continuous rows in the second horizontal direction (Y direction), for example, across the second row R2 and the third row R3. In some embodiments, in the second logic cell region SCR2, one first logic cell UHD may be arranged in each of rows adjacent to the second logic cell HC in the second horizontal direction (Y direction), for example, on each of the first row R1 and the fourth row R4. A plurality of filler cells FC may be arranged in the filler cell region FCR.

The second logic cell HC arranged in the second logic cell region SCR2 may be aligned in the first horizontal direction (X direction) with two first logic cells UHD arranged in the second horizontal direction (Y direction) in the first logic cell region SCR1. For example, the second logic cell HC arranged across the second row R2 and the third row R3 in the second logic cell region SCR2 may be aligned in the first horizontal direction (X direction) with two first logic cells UHD arranged on the second row R2 and the third row R3 in the first logic cell region SCR1. For example, one of both ends of the second logic cell HC arranged across the second row R2 and the third row R3 in the second logic cell region SCR2 in the second horizontal direction (Y direction) may be aligned in the first horizontal direction (X direction) with one of both ends of the first logic cell UHD arranged on the second row R2 in the first logic cell region SCR1 in the second horizontal direction (Y direction) toward the first row R1, and the other of both ends of the second logic cell HC arranged across the second row R2 and the third row R3 in the second logic cell region SCR2 in the second horizontal direction (Y direction) may be aligned in the first horizontal direction (X direction) with one of both ends of the first logic cell UHD arranged on the third row R3 in the first logic cell region SCR1 in the second horizontal direction (Y direction) toward the fourth row R4.

The first logic cell UHD arranged on each of both sides of the second logic cell HC in the second horizontal direction (Y direction), for example, the first logic cell UHD arranged on each of the first row R1 and the fourth row R4 in the second logic cell region SCR2, may be aligned in the first horizontal direction (X direction) with another first logic cell UHD close thereto in the first horizontal direction (X direction), for example, the first logic cell UHD arranged on a corresponding row of the first row R1 and the fourth row R4 in the first logic cell region SCR1.

The integrated circuit device 10 according to the inventive concept may include the first logic cell UHD and the second logic cell HC having different cell heights to improve operation reliability, and because an offset does not occur between the first logic cell UHD and the second logic cell HC, waste of area in the integrated circuit device 10 may be reduced, and accordingly, the degree of integration may be improved.

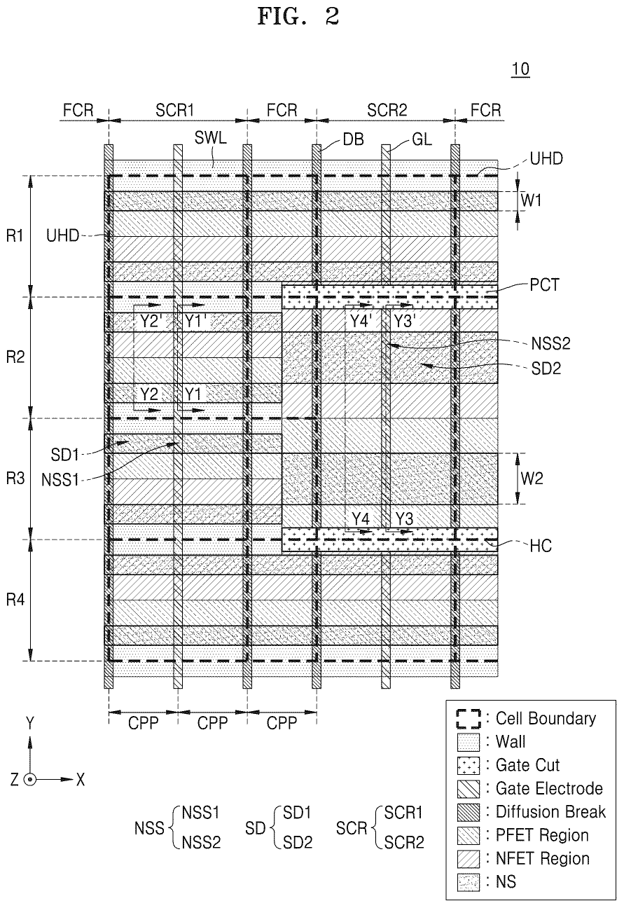

FIG. 2 is a diagram of a layout of the integrated circuit device 10 according to embodiments.

Referring to FIG. 2, the layout of the integrated circuit device 10 may include a plurality of nanosheet layers NS extending in the first horizontal direction (X direction), and a plurality of gate electrodes GL and a plurality of diffusion brakes DB extending in the second horizontal direction (Y direction). A plurality of nanosheet stacked structures NSS may be arranged in portions of a plurality of nanosheet layers NS that overlap a plurality of gate electrodes GL in a vertical direction (Z direction), and a plurality of source/drain regions SD may be arranged in portions of the plurality of nanosheet layers NS that do not overlap the plurality of gate electrodes GL. For example, after the plurality of nanosheet layers NS and the plurality of gate electrodes GL are formed, by removing portions of the plurality of nanosheet layers NS that do not overlap with the plurality of gate electrodes GL in the vertical direction (Z direction), the plurality of nanosheet stacked structures NSS, which are other portions of the plurality of nanosheet layers NS remaining in portions intersecting the plurality of gate electrodes GL, may be formed, and the plurality of source/drain regions SD connected to the plurality of nanosheet stacked structures NSS may be formed in portions where the plurality of nanosheet layers NS have been removed. The plurality of source/drain regions SD may be formed to be connected to the plurality of nanosheet stacked structures NSS on both sides of the plurality of gate electrodes GL in the first horizontal direction (X direction).

The integrated circuit device 10 may include the plurality of logic cell regions SCR and the plurality of filler cell regions FCR arranged on the X-Y plane formed by the first horizontal direction (X direction) and the second horizontal direction (Y direction). One of the filler cell region FCR may be arranged between a pair of the logic cell regions SCR adjacent to one another in the first horizontal direction (X direction). One of the logic cell region SCR may be arranged between a pair of the filler cell regions FCR adjacent to one another in the first horizontal direction (X direction). The standard cells may be arranged in the integrated circuit device 10. The standard cell may include the first logic cell UHD, the second logic cell HC, and the filler cell FC. The first logic cell UHD and the second logic cell HC may be arranged in the logic cell region SCR, and the filler cell FC may be arranged in the filler cell region FCR.

In the integrated circuit device 10, one contact poly pitch CPP may constitute the filler cell region FCR in the first horizontal direction (X direction), and two contact poly pitches CPP may constitute the logic cell region SCR in the first horizontal direction (X direction). For reference, the contact poly pitch CPP may mean a pitch of the gate electrode GL in the first horizontal direction (X direction). For example, the gate electrodes GL and the diffusion brakes DB may be arranged with the contact poly pitch CPP as a pitch in the first horizontal direction (X direction). After the plurality of gate electrodes GL are formed, and portions thereof are removed, the removed portions may be replaced with the diffusion brakes DB. In other words, before the diffusion brakes DB are replaced, the plurality of gate electrodes GL may be arranged with the contact poly pitch CPP as a pitch in the first horizontal direction (X direction). The diffusion brakes DB may be arranged at both ends of each of the logic cell region SCR and the filler cell region FCR in the first horizontal direction (X direction). For example, the diffusion brake DB may be arranged between the logic cell region SCR and the filler cell region FCR adjacent to one another in the first horizontal direction (X direction).

The plurality of logic cell regions SCR may include the first logic cell region SCR1 and the second logic cell region SCR2 adjacent to the first logic cell region SCR1 in the first horizontal direction (X direction). The first logic cells UHD may be arranged in the first logic cell region SCR 1 in the second horizontal direction (Y direction). For example, in the first logic cell region SCR1, one of the first logic cell UHD may be arranged in each of the first through fourth rows R1 through R4. In the second logic cell region SCR2, the first logic cells UHD and at least one of the second logic cell HC may be arranged in the second horizontal direction (Y direction). For example, in the second logic cell region SCR2, one of the second logic cell HC may be arranged across two continuous rows of the first through fourth rows R1 through R4 in the second horizontal direction (Y direction), for example, across the second row R2 and the third row R3, and one of the first logic cell UHD may be arranged on each of the first row R1 and the fourth row R4, that are rows adjacent to the second logic cell HC in the second horizontal direction (Y direction).

In some embodiments, a separation wall SWL and/or a gate cut structure PCT may be arranged between the first logic cells UHD and the second logic cell HC along boundaries of the first through fourth rows R1 through R4. For example, the separation wall SWL may be formed between the first logic cells UHD adjacent to one another in the second horizontal direction (Y direction), and the gate cut structure PCT may be formed between the first logic cell UHD and the second logic cell HC adjacent to one another in the second horizontal direction (Y direction). The separation wall SWL may be in contact with a first nanosheet stacked structure NSS1. The gate cut structure PCT may be apart from each of the first nanosheet stacked structure NSS1 and a second nanosheet stacked structure NSS2 without being in contact with the same. The separation wall SWL may be referred to as a separation structure.

Each of the first logic cell UHD and the second logic cell HC may include an n-channel field effect transistor (NFET) region and a p-channel field effect transistor (PFET) region. The gate electrode GL, the nanosheet stacked structure NSS, and the source/drain region SD, which are arranged in the NFET region, may constitute the NFET, and the gate electrode GL, the nanosheet stacked structure NSS, and the source/drain region SD, which are arranged in the PFET region, may constitute the PFET. Each of the first logic cell UHD and the second logic cell HC may constitute the INV including the NFET and the PFET. The NFET and the PFET included in the first logic cell UHD may be referred to as a first NFET and a first PFET, respectively, and the NFET and the PFET included in the second logic cell HC may be referred to as a second NFET and a second PFET, respectively. In some embodiments, the NFET region and the PFET region illustrated in FIG. 2 may be configured in reverse. For example, the PFET region may be arranged in the NFET region illustrated in FIG. 2, and the NFET region may be arranged in the PFET region illustrated in FIG. 2. The NFET region and the PFET region may be referred to as a first conductivity type FET region and a second conductivity type FET region, or a second conductivity type FET region and a first conductivity type FET region, respectively.

In the first logic cell UHD, the NFET region may be formed adjacent to the separation wall SWL and/or the gate cut structure PCT, which are formed along an upper end portion or a lower end portion of a cell boundary of the first logic cell UHD. For example, in the first logic cell UHD, the NFET region may be formed adjacent to the separation wall SWL and/or the gate cut structure PCT, which are formed along the upper end portion of the cell boundary of the first logic cell UHD. In the first logic cell UHD, the PFET region may be formed adjacent to the separation wall SWL and/or the gate cut structure PCT, which are formed along the lower end portion or the upper end portion of the cell boundary of the first logic cell UHD. For example, in the first logic cell UHD, the PFET region may be formed adjacent to the separation wall SWL and/or the gate cut structure PCT, which are formed along the lower end portion of the cell boundary of the first logic cell UHD. In the second logic cell HC, the NFET region may be formed adjacent to the gate cut structure PCT formed along the upper end portion or the lower end portion of the cell boundary of the second logic cell HC. For example, in the second logic cell HC, the NFET region may be formed adjacent to the gate cut structure PCT formed along the upper end portion of the cell boundary of the second logic cell HC. In the second logic cell HC, the PFET region may be formed adjacent to the gate cut structure PCT formed along the lower end portion or the upper end portion of the cell boundary of the second logic cell HC. For example, in the second logic cell HC, the PFET region may be formed adjacent to the gate cut structure PCT formed along the lower end portion of the cell boundary of the second logic cell HC.

The plurality of nanosheet stacked structures NSS may include the first nanosheet stacked structure NSS1 included in the first logic cell UHD and the second nanosheet stacked structure NSS2 included in the second logic cell HC. The plurality of source/drain regions SD may include a first source/drain region SD1 included in the first logic cell UHD and a second source/drain region SD2 included in the second logic cell HC. The first nanosheet stacked structure NSS1 may have a first channel width W1 in the second horizontal direction (Y direction), and the second nanosheet stacked structure NSS2 may have a second channel width W2 in the second horizontal direction (Y direction). For example, each of the first NFET and the first PFET may have the first channel width W1, and each of the second NFET and the second PFET may have the second channel width W2. The second channel width W2 may be greater than the first channel width W1. In some embodiments, the second channel width W2 may be more than twice the first channel width W1.

For example, two NFET regions and two PFET regions may be alternately arranged in the first logic cell region SCR1 in the second horizontal direction (Y direction). The separation wall SWL may be arranged between the NFET regions of a pair of the first logic cells UHD adjacent to one another in the second horizontal direction (Y direction), and between the PFET regions of a pair of the first logic cells UHD adjacent to one another in the second horizontal direction (Y direction). FET regions of the same conductivity type may be arranged on both sides in the second horizontal direction (Y direction) of one of a pair of the gate cut structures PCT at both ends of the second logic cell HC in the second horizontal direction (Y direction), and the FET regions of different conductivity types may be arranged on both sides in the second horizontal direction (Y direction) of the other of the pair of gate cut structures PCT. For example, among a pair of the gate cut structures PCT at both ends of the second logic cell HC in the second horizontal direction (Y direction), on both sides of the gate cut structure PCT on the upper side in the second horizontal direction (Y direction) in FIG. 2, the NFET region of the first logic cell UHD and the NFET region of the second logic cell HC, which have the same conductivity type, may be arranged, and on both sides of the gate cut structure PCT on the lower side in the second horizontal direction (Y direction), the NFET region of the first logic cell UHD and the PFET region of the second logic cell HC, which have different conductivity types, may be arranged.

In some embodiments, each of the first logic cell UHD and the second logic cell HC may include an out-wall cell including the separation wall SWL and/or the gate cut structure PCT, which are formed along a portion of the cell boundary facing in the second horizontal direction (Y direction). In the integrated circuit device 10, the first logic cell UHD may be defined as an area one half of which in the first horizontal direction (X direction) is an area from the gate electrode GL at its center to each of the two of the diffusion brakes DB and one half of which in the second horizontal direction (Y direction) is an area from its center to each of two separation walls SWL, and the second logic cell HC may be defined as an area one half of which in the first horizontal direction (X direction) is an area from the gate electrode GL at its center to each of the two of the diffusion brakes DB and one half of which in the second horizontal direction (Y direction) is an area from its center to each of the two gate cut structures PCT.

The second logic cell HC arranged in the second logic cell region SCR2 may be aligned in the first horizontal direction (X direction) with two first logic cells UHD arranged in the second horizontal direction (Y direction) in the first logic cell region SCR1. For example, the second logic cell HC arranged across the second row R2 and the third row R3 in the second logic cell region SCR2 may be aligned in the first horizontal direction (X direction) with two first logic cells UHD arranged on the second row R2 and the third row R3 in the first logic cell region SCR1. For example, the gate cut structure PCT arranged on both sides of the second logic cell HC in the second horizontal direction (Y direction) arranged across the second row R2 and the third row R3 in the second logic cell region SCR2 may be aligned in the first horizontal direction (X direction) with the separation wall SWL at one end of both ends in the second horizontal direction (Y direction) of the first logic cell UHD arranged on the second row R2 in the first logic cell region SCR1 and with the separation wall SWL at the other end of the both ends in the second horizontal direction (Y direction) of the first logic cell UHD arranged on the third row R3.

Each of the separation wall SWL and the gate cut structure PCT, which are aligned with one another in the first horizontal direction (X direction), may extend from the logic cell region SCR to the inside of the filler cell region FCR. In some embodiments, the separation wall SWL and the gate cut structure PCT, which are aligned in the first horizontal direction (X direction), may be in contact with one another in the filler cell region FCR. The separation wall SWL between two of first logic cells UHD arranged on the second row R2 and the third row R3 in the first logic cell region SCR1 may extend into the filler cell region FCR, but may not extend to the second logic cell region SCR2.

The integrated circuit device 10 according to the inventive concept may improve the operation reliability by improving the first logic cell UHD including the first nanosheet stacked structure NSS1 having the first channel width W1 and the second logic cell HC including the second nanosheet stacked structure NSS2 having the second channel width W2, and because no offset is generated between the first logic cell UHD and the second logic cell HC, may improve the degree of integration by reducing waste of area in the integrated circuit device 10.

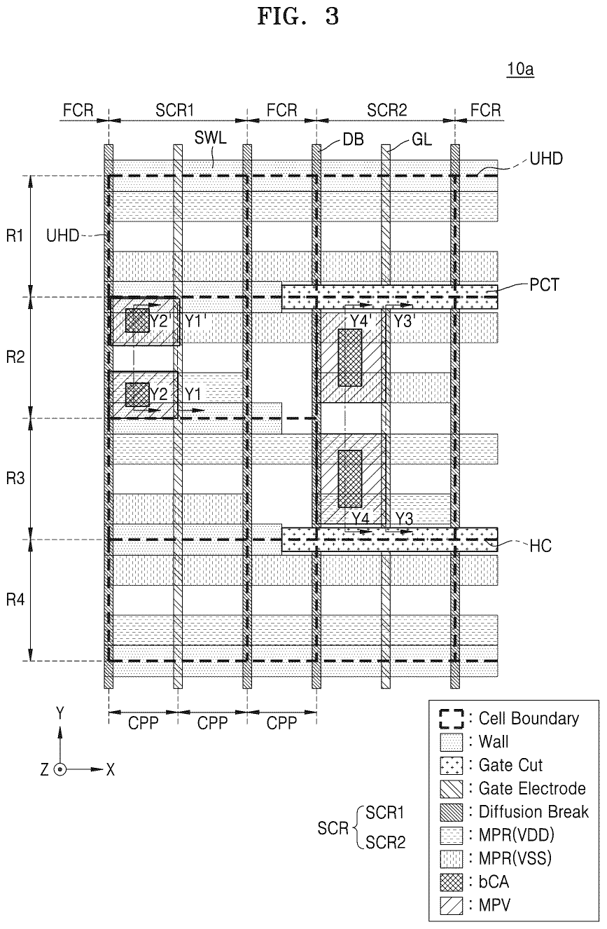

FIG. 3 is a diagram of a layout of an integrated circuit device 10a according to embodiments. The integrated circuit device 10a illustrated in FIG. 3 may indicate a case in which the integrated circuit device 10 illustrated in FIG. 2 has a backside power delivery network (BSPDN), and among contents in FIG. 3, duplicated contents given with reference to FIG. 2 may be omitted.

Referring to FIGS. 2 and 3, the layout of the integrated circuit device 10a may include a plurality of backside power rails MPR extending in the first horizontal direction (X direction), a plurality of backside power vias MPV connected to at least one of the plurality of backside power rails MPR, and a plurality of backside via contacts bCA respectively connecting the plurality of backside power vias MPV to the plurality of source/drain regions SD.

The plurality of backside power rails MPR may include a plurality of first backside power rails MPR(VDD) and a plurality of second backside power rails MPR(VSS). A positive (+) power may be provided to the plurality of first backside power rails MPR(VDD), and a negative (−) power or a ground may be provided to the plurality of second backside power rails MPR(VSS). The plurality of first backside power rails MPR(VDD) may be arranged in the PFET region of the first logic cell UHD and the PFET region of the second logic cell HC, and the plurality of second backside power rails MPR(VSS) may be arranged in the NFET region of the first logic cell UHD and the NFET region of the second logic cell HC.

In the first logic cell UHD, at least one of the first backside power rail MPR(VDD) and at least one of the second backside power rail MPR(VSS) may be arranged, and in the second logic cell HC, at least two of the first backside power rails MPR(VDD) and at least two of the second backside power rails MPR(VSS) may be arranged. In some embodiments, in the first logic cell region SCR1, two of the first backside power rails MPR(VDD) and two of the second backside power rails MPR(VSS) may be alternately arranged in the second horizontal direction (Y direction). Two of the first backside power rails MPR(VDD) arranged in the second logic cell HC may be arranged adjacent to one another in the second horizontal direction (Y direction), and two of the second backside power rails MPR(VSS) may be arranged adjacent to one another in the second horizontal direction (Y direction). Among the plurality of backside power vias MPV, a backside power via MPV arranged in the first logic cell UHD may be connected to at least one of the first backside power rail MPR(VDD) or at least one of the second backside power rail MPR(VSS) arranged in the first logic cell UHD. Among the plurality of backside power vias MPV, the backside power via MPV arranged in the second logic cell HC may be connected to two of the first backside power rail MPR(VDD) adjacent to one another or two of the second backside power rail MPR(VSS) adjacent to one another in the second horizontal direction (Y direction), and may be electrically connected to two of the first backside power rails MPR(VDD) adjacent to one another or two of the second backside power rails MPR(VSS) adjacent to one another in the second horizontal direction (Y direction).

The backside power via MPV may, in the second logic cell HC, be connected to two of the first backside power rails MPR(VDD) adjacent to one another in the second horizontal direction (Y direction) to electrically connect two of the first backside power rails MPR(VDD) adjacent to one another in the second horizontal direction (Y direction) to one another, or in the second logic cell HC, be connected to two of the second backside power rails MPR(VSS) adjacent to one another in the second horizontal direction (Y direction) to electrically connect two of the second backside power rails MPR(VSS) adjacent to one another in the second horizontal direction (Y direction) to one another. The plurality of backside via contacts bCA may be respectively arranged between the plurality of backside power vias MPV and the plurality of source/drain regions SD, which respectively correspond to one another, and may respectively electrically connect the plurality of backside power vias MPV and the plurality of source/drain regions SD, which respectively correspond to one another.

One of the first backside power rail MPR(VDD) among the two of the first backside power rails MPR(VDD) connected to one another via the backside power via MPV may extend from the second logic cell region SCR2 through the filler cell region FCR to the first logic cell region SCR1, and the other of the two of the first backside power rails MPR(VDD) may not extend from the second logic cell region SCR2 into the first logic cell region SCR1. One of the second backside power rails MPR(VSS) among the two of the second backside power rails MPR(VSS) connected to one another via the backside power via MPV may extend from the second logic cell region SCR2 through the filler cell region FCR to the first logic cell region SCR1, and the other of the two of the second backside power rails MPR(VSS) may not extend from the second logic cell region SCR2 into the first logic cell region SCR1.

One of the first backside power rail MPR(VDD) and the second backside power rail MPR(VSS) arranged in the first logic cell UHD adjacent to the second logic cell HC in the first horizontal direction (X direction) may extend into the second logic cell HC adjacent thereto in the first horizontal direction (X direction), and the other thereof may not extend into the second logic cell HC adjacent thereto in the first horizontal direction (X direction). For example, one of the first backside power rail MPR(VDD) and the second backside power rail MPR(VSS) arranged in the first logic cell UHD adjacent to the second logic cell HC in the first horizontal direction (X direction) may extend through the filler cell region FCR into the second logic cell HC adjacent thereto in the first horizontal direction (X direction), and the other thereof may not extend into the filler cell region FCR arranged between the first logic cell UHD and the second logic cell HC.

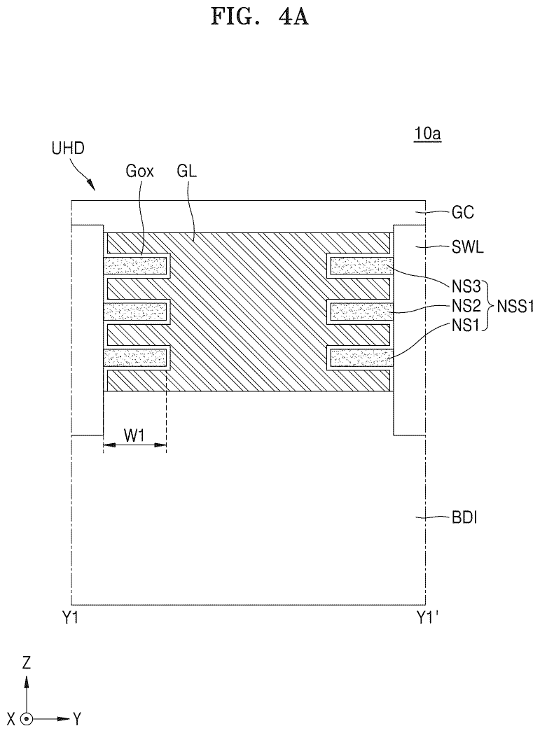

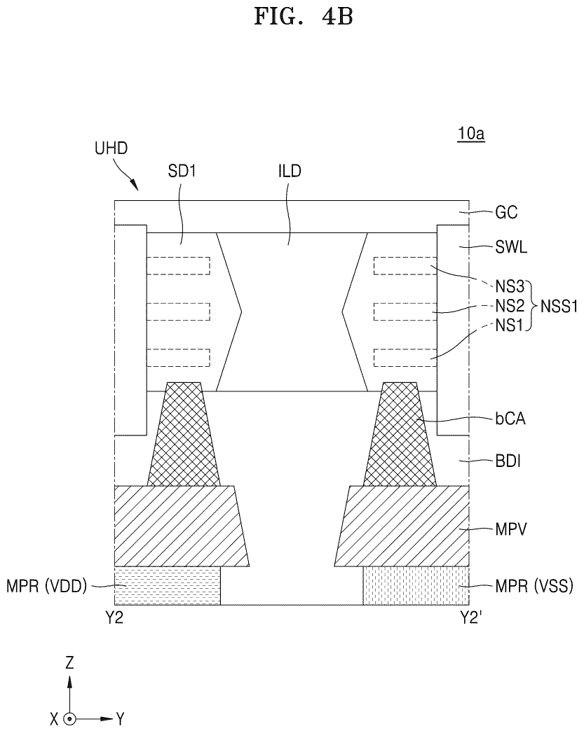

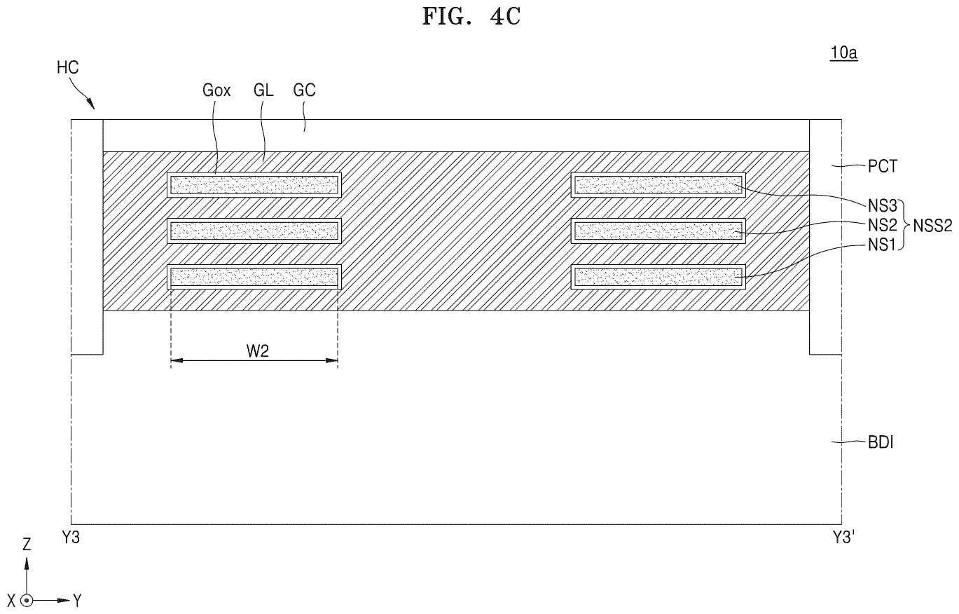

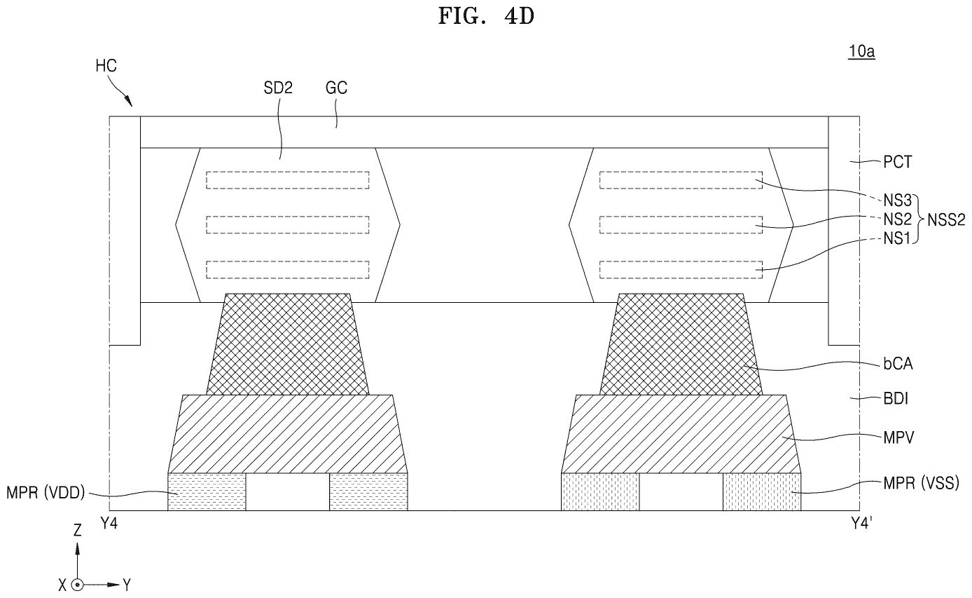

FIGS. 4A through 4D are cross-sectional views of layouts of the integrated circuit device 10a, according to embodiments. FIGS. 4A, 4B, 4C, and 4D are cross-sectional views of the integrated circuit device 10a taken along lines Y1-Y1′, Y2-Y2′, Y3-Y3′, and Y4-Y4′ in FIGS. 2 and 3, respectively.

Referring to FIGS. 2, 3, and 4A through 4D together, the integrated circuit device 10a may include the first nanosheet stacked structures NSS1 and the first source/drain regions SD1 in the first logic cell UHD, the second nanosheet stacked structures NSS2 and the second source/drain regions SD2 in the second logic cell HC, the gate electrodes GL extending in the second horizontal direction (Y direction) and surrounding the first nanosheet stacked structures NSS1 and the second nanosheet stacked structures NSS2, gate insulating layers Gox arranged between the first nanosheet stacked structures NSS1 and the gate electrode GL and between the second nanosheet stacked structure NSS2 and the gate electrodes GL, backside power rails MPR extending in the first horizontal direction (X direction), the backside power vias MPV connected to at least one of the backside power rails MPR, and backside via contacts bCA connecting the backside power vias MPV to the first source/drain regions SD1 and the second source/drain regions SD2. The plurality of backside power rails MPR may include the plurality of first backside power rails MPR(VDD) and the plurality of second backside power rails MPR(VSS).

Each of the first nanosheet stacked structure NSS1 and the second nanosheet stacked structure NSS2 may include a first nanosheet NS1, a second nanosheet NS2, and a third nanosheet NS3, which are sequentially arranged apart from one another from a lower side to an upper side, or in the vertical direction (Z direction), but embodiments is not limited thereto. For example, each of the first nanosheet stacked structure NSS1 and the second nanosheet stacked structure NSS2 may include two or four or more nanosheets. Each of the first nanosheet NS1, the second nanosheet NS2, and the third nanosheet NS3 may include a semiconductor material, such as silicon (Si) and germanium (Ge), or a compound semiconductor material, such as silicon germanium (SiGe), silicon carbide (SiC), gallium arsenide (GaAs), indium arsenide (InAs), and indium phosphide (InP). In some embodiments, each of the first nanosheet NS1, the second nanosheet NS2, and the third nanosheet NS3 may include a semiconductor material, such as Si and Ge. The first source/drain regions SD1 may be connected to both ends of each of the first nanosheet NS1, the second nanosheet NS2, and the third nanosheet NS3 included in the first nanosheet stacked structure NSS1 in the first horizontal direction (X direction), and the second source/drain regions SD2 may be connected to both ends of each of the first nanosheet NS1, the second nanosheet NS2, and the third nanosheet NS3 included in the second nanosheet stacked structure NSS2 in the first horizontal direction (X direction).

Each of the first nanosheet NS1, the second nanosheet NS2, and the third nanosheet NS3 included in the first nanosheet stacked structure NSS1 may have the first channel width W1 in the second horizontal direction (Y direction), and each of the first nanosheet NS1, the second nanosheet NS2, and the third nanosheet NS3 included in the second nanosheet stacked structure NSS2 may have the second channel width W2 in the second horizontal direction (Y direction). The second channel width W2 may be greater than the first channel width W1. In some embodiments, the second channel width W2 may be more than twice the first channel width W1.

Each of the first source/drain region SD1 and the second source/drain region SD2 may include an embedded SiGe structure including a plurality of epitaxially grown SiGe layers, an epitaxially grown Si layer, or an epitaxially grown SiC layer. In some embodiments, the first source/drain regions SD1 and the second source/drain regions SD2 may include impurities of different conductivity types. Each of the first nanosheet stacked structure NSS1 and the second nanosheet stacked structure NSS2 may include impurities of different conductivity types. For example, each of the first source/drain region SD1 and the second source/drain region SD2, which include the NFET, may include n-type impurities, and each of the first nanosheet NS1, the second nanosheet NS2, and the third nanosheet NS3 included in each of the first nanosheet stacked structure NSS1 and the second nanosheet stacked structure NSS2, which include the NFET, may include p-type impurities. For example, each of the first source/drain region SD1 and the second source/drain region SD2, which include the PFET, may include p-type impurities, and each of the first nanosheet NS1, the second nanosheet NS2, and the third nanosheet NS3 included in each of the first nanosheet stacked structure NSS1 and the second nanosheet stacked structure NSS2, which include the PFET, may include n-type impurities.

The gate insulating layers Gox may be formed to conformally cover surfaces of the first nanosheet NS1, the second nanosheet NS2, and the third nanosheet NS3, which are included in each of the first nanosheet stacked structure NSS1 and the second nanosheet stacked structure NSS2. The gate insulating layer Gox may include silicon oxide, a high dielectric material, or a combination thereof. In some embodiments, the gate insulating layer Gox may have a stacked structure including an interface layer and a high dielectric material layer. The interface layer may include a low-k material having a dielectric constant of about 9 or less. For example, the interface layer may include oxide, nitride, or oxynitride. The high dielectric material may include metal oxide or metal oxynitride. The high dielectric material may include a material having a higher dielectric constant than silicon oxide. For example, the high dielectric material may have a dielectric constant of about 10 to about 25. The high dielectric material may include hafnium oxide, hafnium oxynitride, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, and a combination thereof, but is not limited thereto. The high dielectric material may be formed by performing an atomic layer deposition (ALD) process, a chemical vapor deposition (CVD) process, or a physical vapor deposition (PVD) process. The high dielectric material may have a thickness of about 10 Å to about 40 Å, but is not limited thereto. In some embodiments, the interface layer may be omitted. For example, the gate insulating layer Gox may include HfO₂, Al₂O₃, HfAlO₃, Ta₂O₃, or TiO₂.

The gate electrodes GL may include the gate insulating layers Gox therebetween, and may surround the first nanosheet NS1, the second nanosheet NS2, and the third nanosheet NS3, which are included in each of the first nanosheet stacked structure NSS1 and the second nanosheet stacked structure NSS2. In some embodiments, the gate electrode GL may surround an upper surface, a lower surface, and one side surface of both side surfaces in the second horizontal direction (Y direction) of each of the first nanosheet NS1, the second nanosheet NS2, and the third nanosheet NS3, which are included in the first nanosheet stacked structure NSS1. The other side surface of both side surfaces in the second horizontal direction (Y direction) of each of the first nanosheet NS1, the second nanosheet NS2, and the third nanosheet NS3, which are included in the first nanosheet stacked structure NSS1, may be in contact with the separation wall SWL. In some embodiments, the gate electrode GL may surround an upper surface, a lower surface, and both side surfaces in the second horizontal direction (Y direction) of each of the first nanosheet NS1, the second nanosheet NS2, and the third nanosheet NS3, which are included in the second nanosheet stacked structure NSS2.

The gate electrode GL may include a metal-containing layer for adjusting a work function and a metal-containing layer for gap-fill filling an upper space of the metal-containing layer for adjusting a work function. metal-containing layer for adjusting a work function may include at least one metal of Ti, W, Ru, Nb, Mo, Hf, Ni, Co, Pt, Yb, Tb, Dy, Er, and Pd. In some embodiments, the gate electrode GL may have a structure in which a metal nitride layer, a metal layer, a conductive capping layer, and the metal-containing layer for gap-fill are sequentially stacked. The metal nitride layer and the metal layer may include at least one metal of Ti, Ta, W, Ru, Nb, Mo, and Hf. The metal-containing layer for gap-fill may include a W layer or an Al layer. In some embodiments, the gate electrode GL may have a stacked structure of TiAIC/TiN/W, a stacked structure of TiN/TaN/TiAIC/TiN/W, or a stacked structure of TiN/TaN/TiN/TiAIC/TiN/W, but is not limited thereto. The gate capping layer GC may cover the upper surface of the gate electrode GL. For example, the gate capping layer GC may include silicon nitride.

The interlayer insulating layer ILD may fill between the first source/drain regions SD1, between the second source/drain regions SD2, and between the gate electrodes GL. For example, the interlayer insulating layer ILD may include silicon oxide or an insulating material having a lower dielectric constant than silicon oxide. In some embodiments, the interlayer insulating layer ILD may include boro-phospho-silicate glass (BPSG), phosphosilicate glass (PSG), borosilicate glass (BSG), undoped silicate glass (USG), tetraethyleortho silicate (TEOS), high density plasma (HDP), Tonen SilaZene (TOSZ), an ultra-low dielectric constant K (ULK) material having an ultra-low dielectric constant K of about 2.2 to about 2.4, or a combination thereof. The ULK material may include SiOC or SiCOH.

The backside insulating layer BDI may cover bottoms of the gate electrodes GL, the first source/drain regions SD1, the second source/drain regions SD2, and the interlayer insulating layer ILD. The backside insulating layer BDI may include BPSG, PSG, BSG, USG, TEOS, high density plasma (HDP), Tonen SilaZene (TOSZ), an ULK layer, or a combination thereof.

In some embodiments, each of the separation wall SWL and the gate cut structure PCT may extend into the backside insulating layer BDI. Each of the separation wall SWL and the gate cut structure PCT may include an insulating material. For example, each of the separation wall SWL and the gate cut structure PCT may include silicon nitride. In some embodiments, the upper surface of the gate cut structure PCT may be arranged at the same vertical level as the gate capping layer GC to be coplanar.

In the backside insulating layer BDI, the backside power rails MPR extending in the first horizontal direction (X direction), the backside power vias MPV connected to at least one of the backside power rails MPR on the backside power rails MPR, and the backside via contacts bCA connecting the first source/drain regions SD1 and the second source/drain regions SD2 to the backside power vias MPV on the backside power vias MPV may be arranged. In some embodiments, the lower surfaces of the backside power rails MPR may be arranged at the same vertical level as the lower surface of the backside insulating layer BDI to be coplanar. The backside via contacts bCA may be connected to bottoms of the first source/drain regions SD1 and the second source/drain regions SD2. In some embodiments, the backside via contacts bCA may extend from the inside of the backside insulating layer BDI into the first source/drain regions SD1 and the second source/drain regions SD2.

In the first logic cell UHD, at least one of the first backside power rail MPR(VDD) and at least one of the second backside power rail MPR(VSS) may be arranged, and in the second logic cell HC, at least two of the first backside power rails MPR(VDD) and at least two of the second backside power rails MPR(VSS) may be arranged. Two of the first backside power rails MPR(VDD) arranged in the second logic cell HC may be arranged adjacent to one another in the second horizontal direction (Y direction), and two of the second backside power rails MPR(VSS) may be arranged adjacent to one another in the second horizontal direction (Y direction). Among the backside power vias MPV, a backside power via MPV arranged in the first logic cell UHD may be connected to at least one of the first backside power rail MPR(VDD) or at least one of the second backside power rail MPR(VSS) arranged in the first logic cell UHD. Among the backside power vias MPV, the backside power via MPV arranged in the second logic cell HC may be connected to two of the first backside power rail MPR(VDD) adjacent to one another or two of the second backside power rail MPR(VSS) adjacent to one another in the second horizontal direction (Y direction), and may be electrically connected to two of the first backside power rails MPR(VDD) adjacent to one another or two of the second backside power rails MPR(VSS) adjacent to one another in the second horizontal direction (Y direction).

The backside via contacts bCA may be arranged between the first source/drain regions SD1 and the second source/drain regions SD2, and the backside power vias MPV corresponding to the first source/drain regions SD1 and the second source/drain regions SD2.

In some embodiments, a metal silicide layer may be respectively arranged between the first source/drain regions SD1 and the second source/drain regions SD2, and the backside via contacts bCA. For example, the metal silicide layer may include tungsten silicide (WSi), titanium silicide (TiSi), cobalt silicide (CoSi), or nickel silicide (NiSi).

Each of the backside power rails MPR, the backside power vias MPV, and the backside via contacts bCA may include a metal material, such as W, Al, Cu, Ti, Ta, Ru, Mn, and Co, a metal nitride, such as TiN, TaN, CON, and WN, or an alloy, such as cobalt tungsten phosphide (CoWP), cobalt tungsten boron (CoWB), and cobalt tungsten boron phosphide (CoWBP). In some embodiments, the backside power rail MPR connected to the backside power via MPV, the backside power via MPV connected to the backside via contact bCA, or the backside power rail MPR, the backside power via MPV, and the backside via contact bCA, which are connected to one another, may be formed together to one body.

By using an arrangement of the plurality of backside power rails MPR, the plurality of backside power vias MPV, and the plurality of backside via contacts bCA, the integrated circuit device 10a according to the inventive concept may prevent an occurrence of an offset between the first logic cell UHD and the second logic cell HC, which have different cell heights, and accordingly, may improve the operation reliability and the degree of integration.

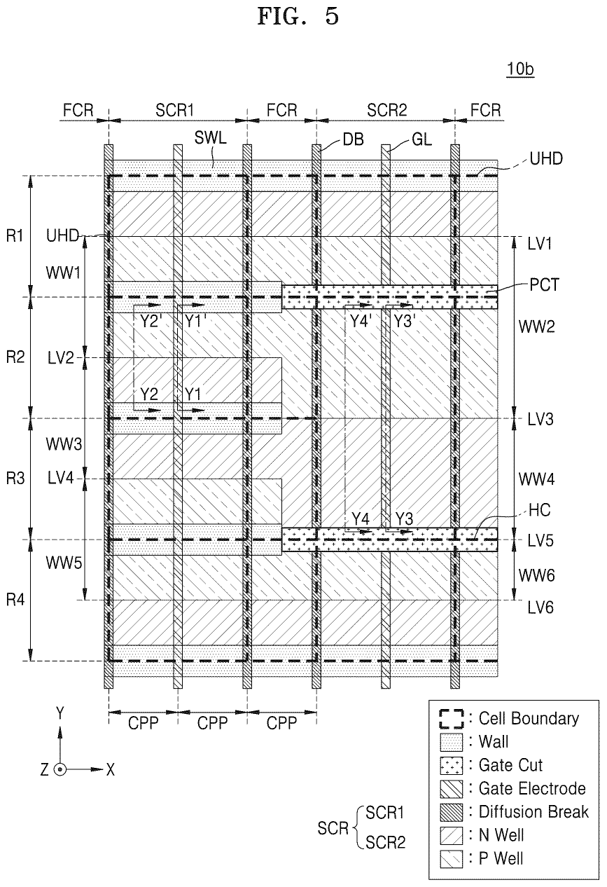

FIG. 5 is a diagram of a layout of an integrated circuit device 10b according to embodiments. The integrated circuit device 10b illustrated in FIG. 5 may indicate a case in which the integrated circuit device 10 illustrated in FIG. 2 has a front side power delivery network (FSPDN), and among contents in FIG. 5, duplicated contents given with reference to FIG. 2 may be omitted.

Referring to FIGS. 2 and 5, a layout of the integrated circuit device 10b may include N wells and P wells. The N wells may be formed in the PFET region illustrated in FIG. 2, and the P wells may be formed in the NFET region illustrated in FIG. 2. In some embodiments, the N wells and the P wells illustrated in FIG. 5 may be configured in reverse. For example, the P wells may be formed instead of the N wells illustrated in FIG. 5, and the N wells may be formed instead of the P wells illustrated in FIG. 5. The N well and the P well may be referred to as a first conductivity type well and a second conductivity type well, or a second conductivity type well and a first conductivity type well, respectively. A portion of the P well and a portion of the N well may be arranged in the second logic cell HC. The NFET included in the second logic cell HC may be formed in the portion of the P well, and the PFET included in the second logic cell HC may be formed in the portion of the N well.

The portion of the P well arranged in the second logic cell HC, a portion of the P well arranged in the first logic cell UHD adjacent to the portion of the P well arranged in the second logic cell HC in the first horizontal direction (X direction), a portion of the P well arranged in the first logic cell UHD adjacent to the portion of the P well arranged in the second logic cell HC in the second horizontal direction (Y direction), and a portion of the P well arranged in each of the first logic cells UHD adjacent to the portion of the P well arranged in the second logic cell HC in diagonal directions with respect to the first horizontal direction (X direction) and the second horizontal direction (Y direction) may constitute a single P well forming one body. A single P well, which is arranged in the second logic cell HC and in the first logic cell UHD adjacent to the P well arranged in the second logic cell HC, and is formed in one body, may have the first well horizontal width WW1 in the first logic cell region SCR1 in the second horizontal direction (Y direction), and may have the second well horizontal width WW2 greater than the first well horizontal width WW1 in the second logic cell region SCR2. The second well horizontal width WW2 may be between 1 time and 2 times the first well horizontal width WW1. In some embodiments, the second well horizontal width WW2 may be about 1.5 times the first well horizontal width WW1, but is not limited thereto.

One end of a single P well in the second horizontal direction (Y direction), which is arranged in the second logic cell HC and in the first logic cell UHD adjacent to a portion of the P well arranged in the second logic cell HC, and is formed in one body, may be arranged at the same first level LV1 in each of the first logic cell region SCR1 and the second logic cell region SCR2, and the other thereof may be arranged at the second level LV2 in the first logic cell region SCR1 and at the third level LV3 in the second logic cell region SCR2. The third level LV3 may be farther from the first level LV1 than the second level LV2 in the second horizontal direction (Y direction).

A portion of the N well arranged in the second logic cell HC and a portion of the N well arranged in each of first logic cells UHD adjacent to the second logic cell HC in the first horizontal direction (X direction) may constitute a single N well forming one body. A single N well, which is arranged in the second logic cell HC and in the first logic cell UHD adjacent to the second logic cell HC, and is formed in one body, may have the third well horizontal width WW3 in the first logic cell region SCR1 in the second horizontal direction (Y direction), and may have the fourth well horizontal width WW4 in the second logic cell region SCR2. The third well horizontal width WW3 and the fourth well horizontal width WW4 may be the same as or substantially similar to one another.

One end of a single N well in the second horizontal direction (Y direction), which is arranged in the second logic cell HC and in the first logic cell UHD adjacent to the second logic cell HC, and is formed in one body, may be arranged at the second level LV2 in the first logic cell region SCR1 and at the third level LV3 in the second logic cell region SCR2, and the other thereof may be arranged at the fourth level LV4 in the first logic cell region SCR1 and at the fifth level LV5 in the second logic cell region SCR2. The fifth level LV5 may be farther from the third level LV3 than the fourth level LV4 in the second horizontal direction (Y direction).

A portion of the P well arranged in the first logic cell UHD adjacent to a portion of the N well arranged in the second logic cell HC in the first horizontal direction (X direction), a portion of the P well arranged in the first logic cell UHD adjacent to the portion of the N well arranged in the second logic cell HC in the second horizontal direction (Y direction), and a portion of the P well arranged in the first logic cell UHD adjacent to the portion of the N well arranged in the second logic cell HC in a diagonal direction with respect to the first horizontal direction (X direction) and the second horizontal direction (Y direction) may constitute a single P well formed in one body. A single P well, which is arranged in the first logic cells UHD adjacent to the N well arranged in the second logic cell HC, and is formed in one body, may have the fifth well horizontal width WW5 in the first logic cell region SCR1 in the second horizontal direction (Y direction), and may have the sixth well horizontal width WW6 less than the fifth well horizontal width WW5 in the second logic cell region SCR2. The fifth well horizontal width WW5 may be between 1 time and 2 times the sixth well horizontal width WW6. In some embodiments, the fifth well horizontal width WW5 may be about 2 times the sixth well horizontal width WW6, but is not limited thereto.

One end in the second horizontal direction (Y direction) of one P well arranged in the first logic cells UHD adjacent to a portion of the N well arranged in the second logic cell HC and formed in one body may be at the fourth level LV4 in the first logic cell region SCR1 and at the fifth level LV5 in the second logic cell region SCR2, and the other end may be at the same sixth level LV6 in the first logic cell region SCR1 and the second logic cell region SCR2. The sixth level LV6 may be farther from the fourth level LV4 than the fifth level LV5 in the second horizontal direction (Y direction).

In the specification, a level may not indicate a position difference in the vertical direction (Z direction), but indicate a position difference in a cell height direction in a plan layout, that is, in the second horizontal direction (Y direction). In the specification, the first level LV1, the second level LV2, the third level LV3, the fourth level LV4, the fifth level LV5, and the sixth level LV6 may mean positions sequentially different from one another in a reverse direction of the second horizontal direction (Y direction).

Each of the N wells and the P wells in the first logic cells UHD arranged adjacent to the second logic cell HC in the first logic cell region SCR1 in the first horizontal direction (X direction) may have a planar shape extending from the first logic cell region SCR 1 to the second logic cell region SCR2 and having a jog in which a well horizontal width is changed or shifted in the second horizontal direction (Y direction). For example, at least one end of both ends in the second horizontal direction (Y direction) of each of the N wells and the P wells in the first logic cells UHD adjacent to the second logic cell HC in the first horizontal direction (X direction) and arranged in the first logic cell region SCR1 may extend from the first logic cell region SCR1 to the second logic cell region SCR2 and have a varying level in the second horizontal direction (Y direction). In some embodiments, a planar shape of each of the N wells and the P wells in the first logic cells UHD adjacent to the second logic cell HC in the first horizontal direction (X direction) and arranged in the first logic cell region SCR1 may extend from the first logic cell region SCR1 to the second logic cell region SCR2 and have a jog in which the well horizontal width in the filler cell region FCR between the first logic cell region SCR1 and the second logic cell region SCR2 is changed or shifted in the second horizontal direction (Y direction).

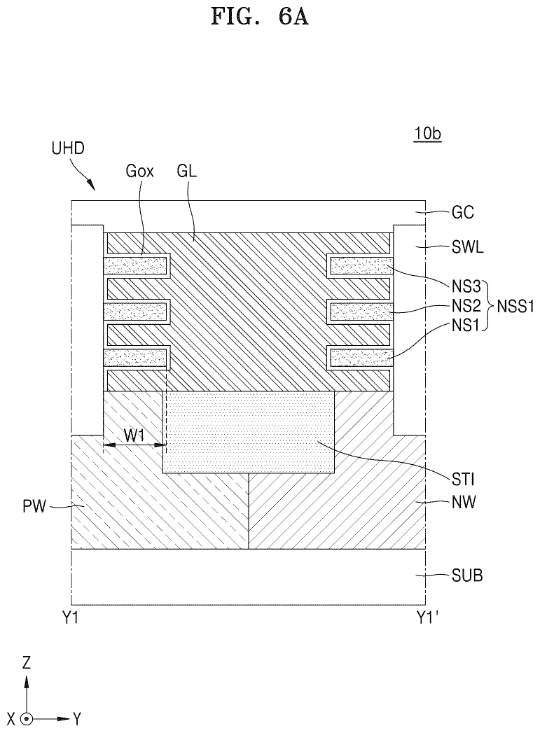

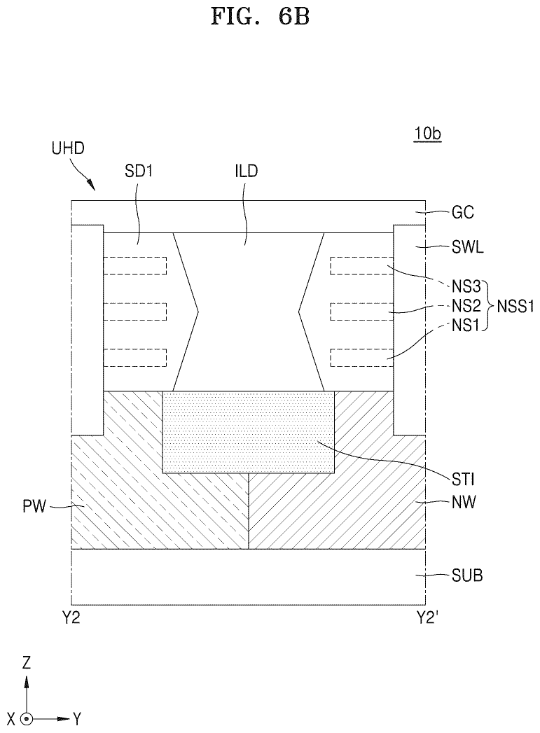

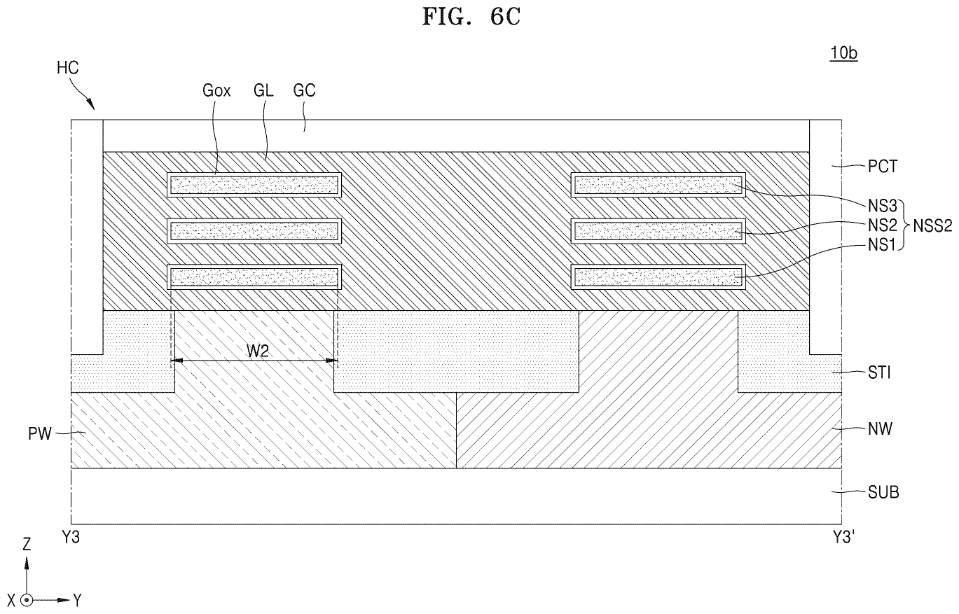

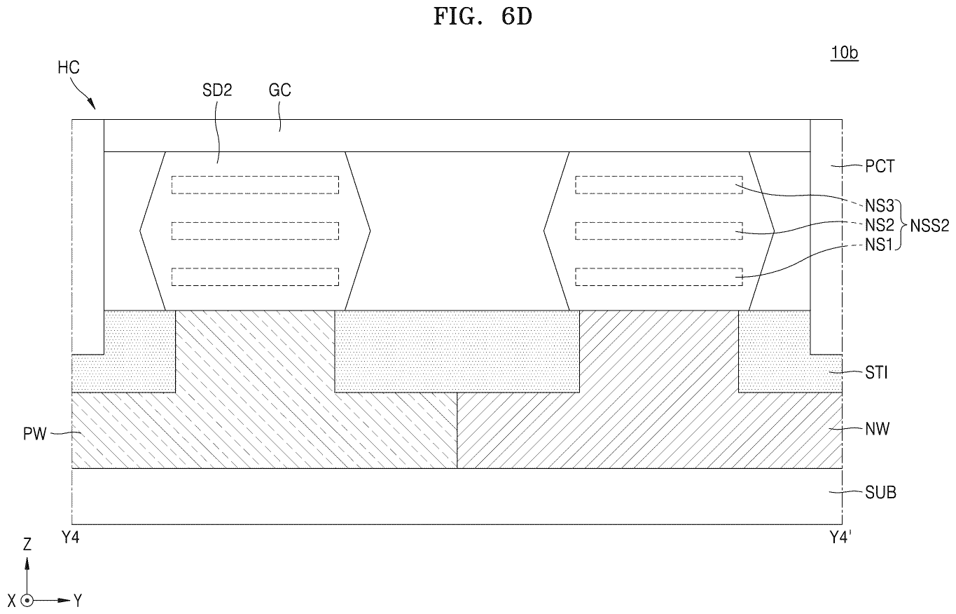

FIGS. 6A through 6D are cross-sectional views of layouts of the integrated circuit device 10b, according to embodiments. FIGS. 6A, 6B, 6C, and 6D are cross-sectional views of the integrated circuit device 10b taken along lines Y1-Y1′, Y2-Y2′, Y3-Y3′, and Y4-Y4′ in FIGS. 2 and 5, respectively.

Referring to FIGS. 2, 5, and 6A through 6D together, the integrated circuit device 10b may include, above the substrate SUB, the first nanosheet stacked structures NSS1 and the first source/drain regions SD1 in the first logic cell UHD, the second nanosheet stacked structures NSS2 and the second source/drain regions SD2 in the second logic cell HC, the gate electrode GL extending in the second horizontal direction (Y direction) and surrounding the first nanosheet stacked structures NSS1 and the second nanosheet stacked structures NSS2, and the gate insulating layers Gox arranged between the first nanosheet stacked structures NSS1 and the gate electrode GL and between the second nanosheet stacked structures NSS2 and the gate electrode GL. N wells NW and P wells PW may be formed in upper portions of a substrate SUB. The N wells NW may be formed in the PFET region illustrated in FIG. 2, and the P wells PW may be formed in the NFET region illustrated in FIG. 2. The N wells NW may be formed by injecting n-type impurities into portions of the upper side of the substrate SUB, and the P wells PW may be formed by injecting p-type impurities into the other portions of the upper side of the substrate SUB.

The substrate SUB may include a semiconductor material, such as Si and Ge, or a compound semiconductor material, such as SiGe, SiC, GaAs, InAs, and InP. In some embodiments, the substrate SUB may include at least one of a Group III-V material and a Group IV material. The III-V material may include a binary, ternary, or quaternary compound semiconductor material including at least one Group III element and at least one Group V element. Device separation layers STI may be formed in a trench formed by removing a portion of an upper side of the substrate SUB. The upper surface of each of the device separation layers STI may be at a vertical level equal to or higher than the upper surface of the substrate SUB, but may be at a vertical level lower than the lower surface of the lowermost first nanosheet NS1 among the first nanosheet NS1, the second nanosheet NS2, and the third nanosheet NS3, which are included in each of the first nanosheet stacked structure NSS1 and the second nanosheet stacked structure NSS2. For example, the device separation layer STI may include silicon oxide, silicon nitride, silicon oxynitride, or a combination thereof. For example, the device separation layer STI may include a material including at least one of silicon oxide, silicon nitride, and silicon oxynitride. The device separation layer STI may include a single layer including one type of an insulating layer, a double layer including two types of insulating layers, or a multiple layer including a combination of at least three types of insulating layers. For example, the device separation layer STI may include two different types of insulating layers. For example, the device separation layer STI may include a silicon oxide layer and a silicon nitride layer. For example, the device separation layer STI may include a triple layer including a silicon oxide layer, a silicon nitride layer, and a silicon oxide layer.

The first source/drain regions SD1 may be connected to both ends of each of the first nanosheet NS1, the second nanosheet NS2, and the third nanosheet NS3 included in the first nanosheet stacked structure NSS1 in the first horizontal direction (X direction), and the second source/drain regions SD2 may be connected to both ends of each of the first nanosheet NS1, the second nanosheet NS2, and the third nanosheet NS3 included in the second nanosheet stacked structure NSS2 in the first horizontal direction (X direction). Each of the first nanosheet NS1, the second nanosheet NS2, and the third nanosheet NS3 included in the first nanosheet stacked structure NSS1 may have the first channel width W1 in the second horizontal direction (Y direction), and each of the first nanosheet NS1, the second nanosheet NS2, and the third nanosheet NS3 included in the second nanosheet stacked structure NSS2 may have the second channel width W2 in the second horizontal direction (Y direction). The second channel width W2 may be greater than the first channel width W1. In some embodiments, the second channel width W2 may be more than twice the first channel width W1.

The gate insulating layers Gox may be formed to conformally cover surfaces of the first nanosheet NS1, the second nanosheet NS2, and the third nanosheet NS3, which are included in each of the first nanosheet stacked structure NSS1 and the second nanosheet stacked structure NSS2. The gate electrodes GL may include the gate insulating layers Gox therebetween, and may surround the first nanosheet NS1, the second nanosheet NS2, and the third nanosheet NS3, which are included in each of the first nanosheet stacked structure NSS1 and the second nanosheet stacked structure NSS2. In some embodiments, the gate electrode GL may surround an upper surface, a lower surface, and one side surface of both side surfaces in the second horizontal direction (Y direction) of each of the first nanosheet NS1, the second nanosheet NS2, and the third nanosheet NS3, which are included in the first nanosheet stacked structure NSS1. The other side surface of both side surfaces in the second horizontal direction (Y direction) of each of the first nanosheet NS1, the second nanosheet NS2, and the third nanosheet NS3, which are included in the first nanosheet stacked structure NSS1, may be in contact with the separation wall SWL. In some embodiments, the gate electrode GL may surround an upper surface, a lower surface, and both side surfaces in the second horizontal direction (Y direction) of each of the first nanosheet NS1, the second nanosheet NS2, and the third nanosheet NS3, which are included in the second nanosheet stacked structure NSS2.

The interlayer insulating layer ILD may fill between the first source/drain regions SD1, between the second source/drain regions SD2, and between the gate electrodes GL, on the substrate SUB and the device separation layer STI. In some embodiments, each of the separation wall SWL and the gate cut structure PCT may extend into the device separation layer STI. The integrated circuit device 10b may include front surface via contacts penetrating a gate capping layer GC and connected to the first source/drain regions SD1, the second source/drain regions SD2, and the gate electrodes GL.

By using shapes and arrangements of the N wells and the P wells, the integrated circuit device 10b according to the inventive concept may prevent occurrence of offset between the first logic cell UHD and the second logic cell HC having different cell heights, and thus, may improve the operation reliability and the degree of integration.

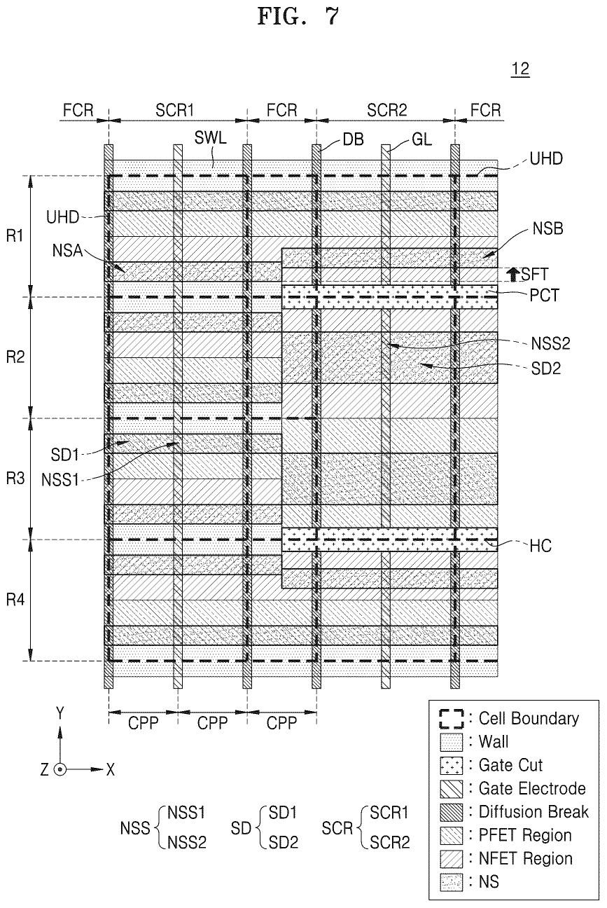

FIG. 7 is a diagram of a layout of an integrated circuit device 12 according to embodiments.

Referring to FIG. 7, the layout of the integrated circuit device 12 may include the plurality of nanosheet layers NS extending in the first horizontal direction (X direction), and the plurality of gate electrodes GL and the plurality of diffusion brakes DB extending in the second horizontal direction (Y direction). The nanosheet layer NS in the first logic cell UHD adjacent to the second logic cell HC in the first horizontal direction (X direction) among the plurality of nanosheet layers NS may have a planar shape having a jog, extending from the first logic cell region SCR1 to the second logic cell region SCR2 and shifting away from the second logic cell HC in the second horizontal direction (Y direction). The nanosheet layer NS in the first logic cell UHD adjacent to the second logic cell HC in the first horizontal direction (X direction) among the plurality of nanosheet layers NS may include a first nanosheet layer NSA in the first logic cell region SCR1 and a second nanosheet layer NSB in the second logic cell region SCR2. The first nanosheet layer NSA may extend into the filler cell region FCR in the first horizontal direction (X direction) from the first logic cell region SCR1 toward the second logic cell region SCR2, and the second nanosheet layer NSB may extend into the filler cell region FCR in the first horizontal direction (X direction) from the second logic cell region SCR2 toward the first logic cell region SCR1. The second nanosheet layer NSB may have a shift size SFT from the first nanosheet layer NSA in a second horizontal direction (Y direction). The shift size SFT may be less than a channel width (the first channel width W1 in FIG. 2) of the first nanosheet stacked structure NSS1. The first nanosheet layer NSA may be in contact with the second nanosheet layer NSB in the filler cell region FCR. For example, a planar shape of the nanosheet layer NS in the first logic cell UHD adjacent to the second logic cell HC in the first horizontal direction (X direction) among the plurality of nanosheet layers NS may have a jog, extend from the first logic cell region SCR1 to the second logic cell region SCR2 and be shifted away from the second logic cell HC in the second horizontal direction (Y direction).

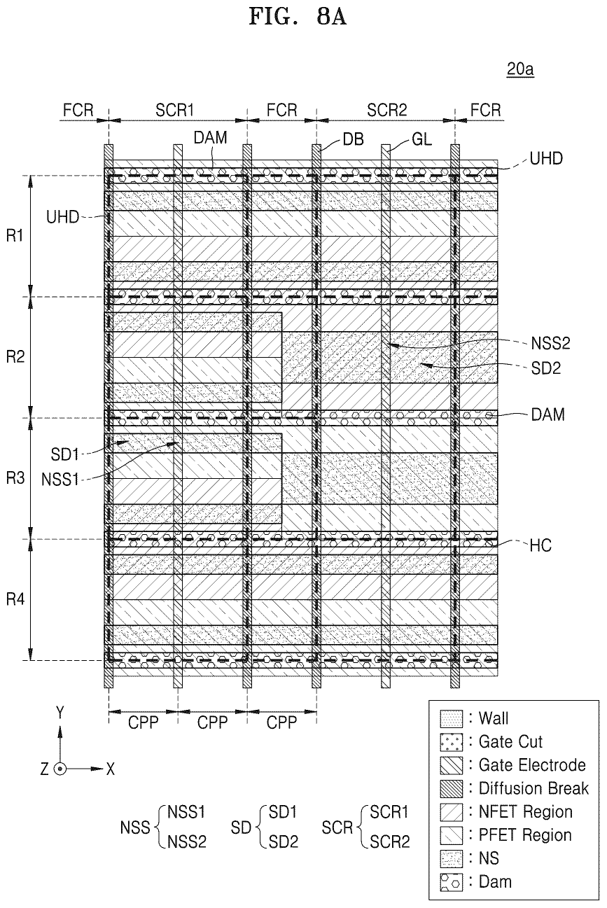

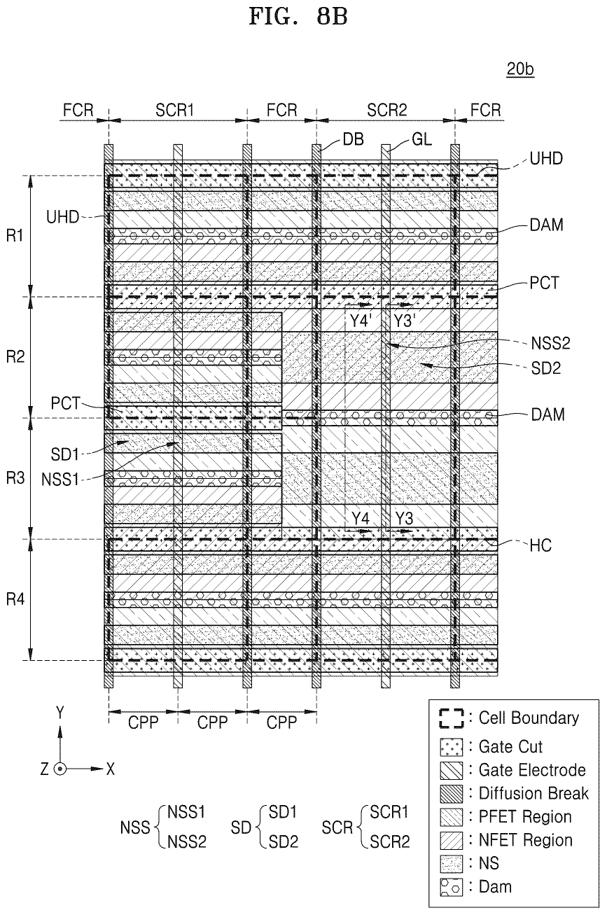

FIGS. 8A and 8B are diagrams of layouts of integrated circuit devices 20a and 20b, respectively, according to embodiments.

Referring to FIG. 8A, the layout of the integrated circuit device 20a may include the plurality of nanosheet layers NS extending in the first horizontal direction (X direction), and the plurality of gate electrodes GL and the plurality of diffusion brakes DB extending in the second horizontal direction (Y direction). The integrated circuit device 20a may include the plurality of logic cell regions SCR and the plurality of filler cell regions FCR arranged on the X-Y plane formed by the first horizontal direction (X direction) and the second horizontal direction (Y direction). One filler cell region FCR may be arranged between a pair of logic cell regions SCR adjacent to one another in the first horizontal direction (X direction). The plurality of logic cell regions SCR may include a first logic cell region SCR1 and a second logic cell region SCR2 adjacent to the first logic cell region SCR1 in the first horizontal direction (X direction). The first logic cells UHD may be arranged in the first logic cell region SCR1 in the second horizontal direction (Y direction). In the second logic cell region SCR2, the first logic cells UHD and at least one of the second logic cell HC may be arranged in the second horizontal direction (Y direction).

The integrated circuit device 20a may include dam structures DAM instead of the separation walls SWL and the gate cut structures PCT included in the integrated circuit device 10 illustrated in FIG. 2, and thus duplicate descriptions thereof are omitted. In some embodiments, the dam structures DAM may be arranged between the first logic cells UHD and the second logic cell HC along boundaries of the first through fourth rows R1 through R4. In FIG. 8A, the dam structure DAM is illustrated to be also arranged between the PFET region and the NFET region of the second logic cell HC, but embodiments is not limited thereto. In some embodiments, the dam structures DAM may be arranged only between the first logic cells UHD and the second logic cell HC along the boundaries of the first through fourth rows R1 through R4, and may not be arranged between the PFET region and the NFET region of the second logic cell HC. The separation walls SWL included in the integrated circuit device 10 illustrated in FIG. 2 may be in contact with the first nanosheet stacked structure NSS1, but the dam structures DAM may be apart from the first nanosheet stacked structure NSS1 without being in contact with the same. The dam structure DAM may be referred to as a separation structure.

Referring to FIG. 8B, the layout of the integrated circuit device 20b may include the plurality of nanosheet layers NS extending in the first horizontal direction (X direction), and the plurality of gate electrodes GL and the plurality of diffusion brakes DB extending in the second horizontal direction (Y direction). The integrated circuit device 20b may include the plurality of logic cell regions SCR and the plurality of filler cell regions FCR arranged on the X-Y plane formed by the first horizontal direction (X direction) and the second horizontal direction (Y direction). One filler cell region FCR may be arranged between a pair of logic cell regions SCR adjacent to one another in the first horizontal direction (X direction). The plurality of logic cell regions SCR may include a first logic cell region SCR1 and a second logic cell region SCR2 adjacent to the first logic cell region SCR1 in the first horizontal direction (X direction). The first logic cells UHD may be arranged in the first logic cell region SCR1 in the second horizontal direction (Y direction). In the second logic cell region SCR2, the first logic cells UHD and at least one of the second logic cell HC may be arranged in the second horizontal direction (Y direction).

In the integrated circuit device 20b, in addition that the gate cut structures PCT included in the integrated circuit device 10 illustrated in FIG. 2, the gate cut structures PCT may be also arranged at positions where the separation walls SWL included in the integrated circuit device 10 illustrated in FIG. 2 are arranged. For example, the gate cut structure PCT may be arranged between the first logic cells UHD and the second logic cell HC along boundaries of the first through fourth rows R1 through R4.

The integrated circuit device 20b may include the dam structures DAM extending between the PFET region and the NFET region of the first logic cell UHD and between the PFET region and the NFET region of the second logic cell HC. The dam structures DAM may be apart from the first nanosheet stacked structure NSS1 and the second nanosheet stacked structure NSS2 without being in contact with the same.

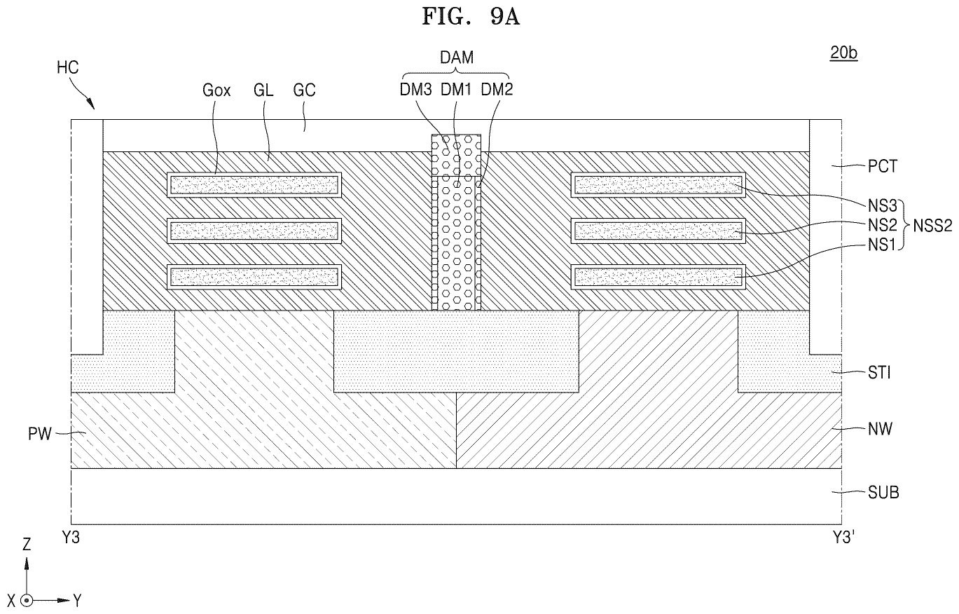

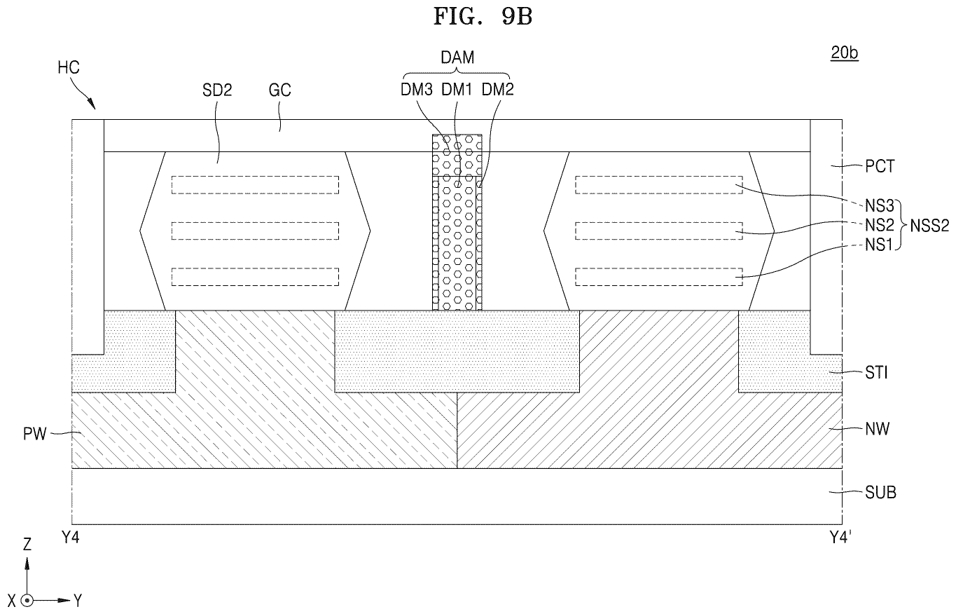

FIGS. 9A and 9B are cross-sectional views of layouts of the integrated circuit device 20b, according to embodiments. FIGS. 9A and 9B are cross-sectional views taken along lines Y3-Y3′ and Y4-Y4′ in FIG. 8B, respectively.

Referring to FIGS. 8B, 9A, and 9B, the integrated circuit device 20b may include, above the substrate SUB, the first nanosheet stacked structures NSS1 and the first source/drain regions SD1 in the first logic cell UHD, the second nanosheet stacked structures NSS2 and the second source/drain regions SD2 in the second logic cell HC, the gate electrode GL extending in the second horizontal direction (Y direction) and surrounding the first nanosheet stacked structures NSS1 and the second nanosheet stacked structures NSS2, and the gate insulating layers Gox arranged between the first nanosheet stacked structures NSS1 and the gate electrode GL and between the second nanosheet stacked structures NSS2 and the gate electrode GL. The N wells NW and the P wells PW may be formed in upper portions of the substrate SUB. The N wells NW may be formed in the PFET region, and the P wells PW may be formed in the NFET region.

The gate insulating layers Gox may be formed to conformally cover surfaces of the first nanosheet NS1, the second nanosheet NS2, and the third nanosheet NS3. The gate electrodes GL may include the gate insulating layers Gox therebetween, and surround the first nanosheet NS1, the second nanosheet NS2, and the third nanosheet NS3. In some embodiments, the gate electrode GL may surround the upper surface, the lower surface, and both side surfaces in the second horizontal direction (Y direction) of each of the first nanosheet NS1, the second nanosheet NS2, and the third nanosheet NS3. The dam structures DAM may be apart from the first nanosheet NS1, the second nanosheet NS2, and the third nanosheet NS3 without being in contact with the same.

The dam structure DAM may include a first dam material layer DM1 and a second dam material layer DM2 covering sidewalls of the first dam material layer DM1. In some embodiments, the second dam material layer DM2 may simultaneously cover the sidewalls and a lower surface of the first dam material layer DM1. Each of the first dam material layer DM1 and the second dam material layer DM2 may include an insulating material. In some embodiments, the first dam material layer DM1 and the second dam material layer DM2 may include different types of insulating materials. For example, the first dam material layer DM1 may include silicon carbonate (SiOCN), and the second dam material layer DM2 may include silicon oxide (SiO). A vertical level of the upper surface of each of the first dam material layer DM1 and the second dam material layer DM2 may be equal to or lower than a vertical level of the upper surface of the gate electrode GL. In some embodiments, the dam structure DAM may further include a third dam material layer DM3 covering the first dam material layer DM1 and the second dam material layer DM2. The third dam material layer DM3 may include a different type of insulating material from each of the first dam material layer DM1 and the second dam material layer DM2. For example, the third dam material layer DM3 may include a high dielectric material. A vertical level of an upper surface of the third dam material layer DM3 may be higher than a vertical level of the upper surface of the gate electrode GL and lower than a vertical level of the upper surface of the gate capping layer GC.

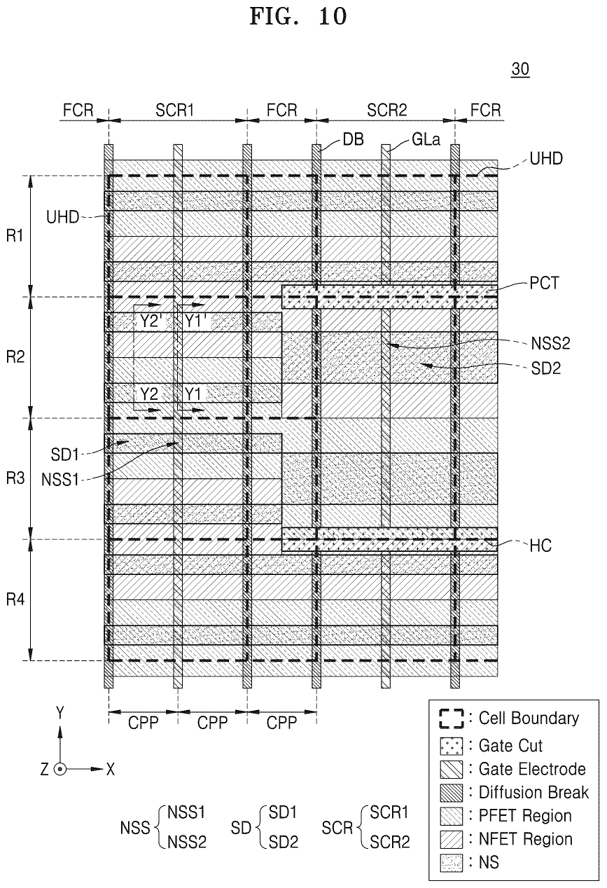

FIG. 10 is a diagram of a layout of an integrated circuit device 30 according to embodiments.

Referring to FIG. 10, the layout of the integrated circuit device 30 may include the plurality of nanosheet layers NS extending in the first horizontal direction (X direction), and a plurality of gate electrodes GLa and the plurality of diffusion brakes DB extending in the second horizontal direction (Y direction). The integrated circuit device 30 may include the plurality of logic cell regions SCR and the plurality of filler cell regions FCR arranged on the X-Y plane formed by the first horizontal direction (X direction) and the second horizontal direction (Y direction). One filler cell region FCR may be arranged between a pair of logic cell regions SCR adjacent to one another in the first horizontal direction (X direction). The plurality of logic cell regions SCR may include a first logic cell region SCR1 and a second logic cell region SCR2 adjacent to the first logic cell region SCR1 in the first horizontal direction (X direction). The first logic cells UHD may be arranged in the first logic cell region SCR1 in the second horizontal direction (Y direction). In the second logic cell region SCR2, the first logic cells UHD and at least one of the second logic cell HC may be arranged in the second horizontal direction (Y direction).

The integrated circuit device 30 may not include the separation walls SWL included in the integrated circuit device 10 illustrated in FIG. 2, and duplicate descriptions given with reference to FIG. 2 are omitted. In some embodiments, the integrated circuit device 30 may include the gate cut structure PCT arranged between the first logic cell UHD and the second logic cell HC adjacent to one another in the second horizontal direction (Y direction). The gate cut structure PCT may be apart from each of the first nanosheet stacked structure NSS1 and the second nanosheet stacked structure NSS2 without being in contact with the same.

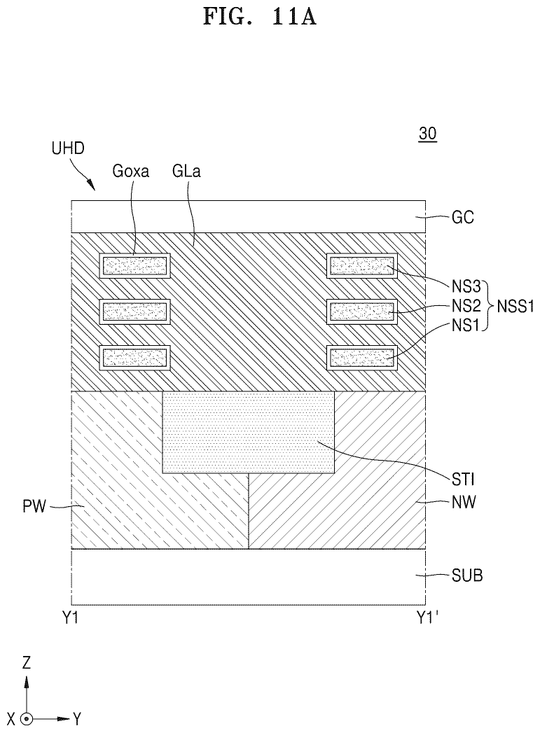

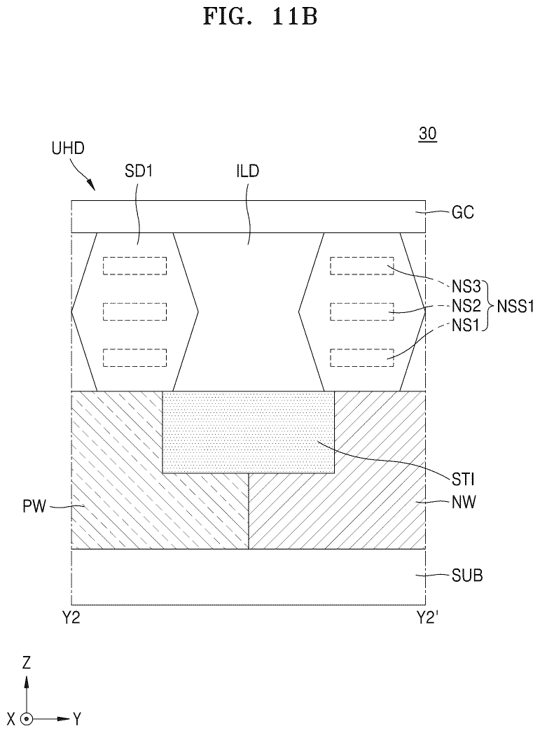

FIGS. 11A and 11B are cross-sectional views of layouts of an integrated circuit device 30, according to embodiments. FIGS. 11A and 11B are cross-sectional views taken along lines Y1-Y1′ and Y2-Y2′ in FIG. 10, respectively.

Referring to FIGS. 10, 11A, and 11B together, the integrated circuit device 30 may include, above the substrate SUB, the first nanosheet stacked structures NSS1 and the first source/drain regions SD1 in the first logic cell UHD, the second nanosheet stacked structures NSS2 and the second source/drain regions SD2 in the second logic cell HC, the gate electrode GL extending in the second horizontal direction (Y direction) and surrounding the first nanosheet stacked structures NSS1 and the second nanosheet stacked structures NSS2, and the gate insulating layers Gox arranged between the first nanosheet stacked structures NSS1 and the gate electrode GL and between the second nanosheet stacked structures NSS2 and the gate electrode GL. N wells NW and P wells PW may be formed in upper portions of a substrate SUB. The N wells NW may be formed in the PFET region, and the P wells PW may be formed in the NFET region.

Gate insulating layers Goxa may be formed to conformally cover the surfaces of the first nanosheet NS1, the second nanosheet NS2, and the third nanosheet NS3. The gate electrodes GLa may include the gate insulating layers Goxa therebetween, and surround the first nanosheet NS1, the second nanosheet NS2, and the third nanosheet NS3. In some embodiments, the gate electrode GLa may surround the upper surface, the lower surface, and both side surfaces in the second horizontal direction (Y direction) of each of the first nanosheet NS1, the second nanosheet NS2, and the third nanosheet NS3.

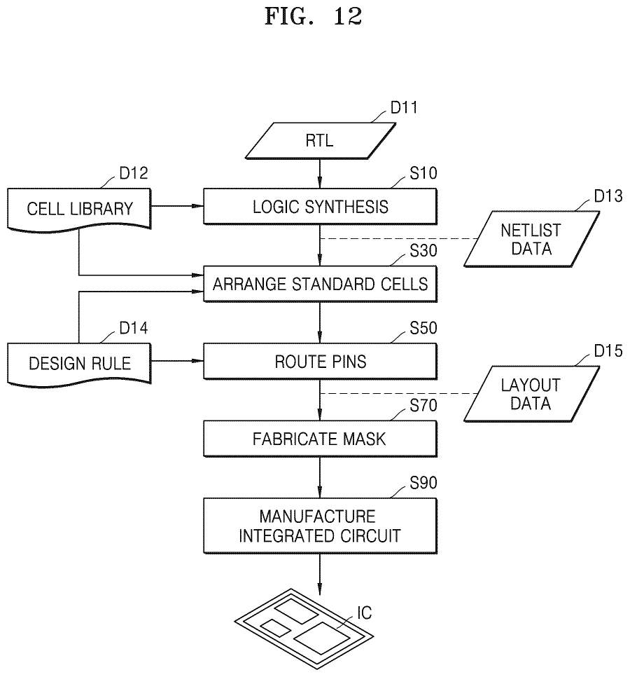

FIG. 12 is a flowchart of a method of manufacturing an integrated circuit device IC according to embodiments.

Referring to FIG. 12, a method for manufacturing the integrated circuit device IC may include a plurality of operations S10, S30, S50, S70, and S90. A cell library (or standard cell library) D12 may include information about standard cells, such as function information, characteristics information, and layout information. Design rule D14 may include requirements to be complied with by the layout of the integrated circuit device IC. For example, the design rule D14 may include requirements for the distance between patterns on the same wiring layer, a minimum width of a pattern, a routing direction of a wiring layer, etc. In some embodiments, the design rule D14 may include a minimum distance between the nanosheet layer and the gate cut structure, a pitch of gate electrodes, etc.

In operation S10, input data defining the integrated circuit device IC including standard cells may be obtained. For example, a logic synthesis operation of generating netlist data D13 from register-transfer-level (RTL) data D11 may be performed. For example, a semiconductor design tool (for example, a logic synthesis tool) may generate the netlist data D13 including a bitstream or a netlist, by performing a logic synthesis with reference to the cell library D12 from the RTL data D11 that is prepared in a hardware description language (HDL), such as very high speed integrated circuit (VHSIC) hardware description language (VHDL) and Verilog. The netlist data D13 may correspond to an input of placement and routing to be described below.

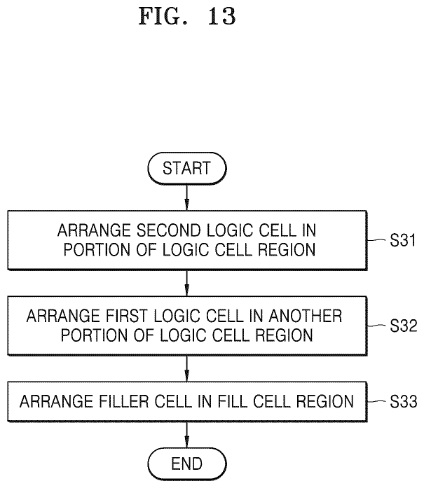

In operation S30, the standard cells may be arranged. For example, a semiconductor design tool (for example, a placement and routing (P&R) tool) may arrange the standard cells used by the netlist data D13 with reference to the cell library D12. In some embodiments, a first logic cell and a second logic cell may be arranged in a logic cell region, and a filler cell may be arranged in a filler cell region. An example of operation S30 is described with reference to FIG. 13 below.

In operation S50, pins of cells may be routed. For example, a semiconductor design tool may generate interconnections electrically connecting output pins to input pins of the arranged standard cells, and may generate the layout data D15 defining the layout defining the arranged standard cells and the generated interconnections. The interconnection may include a via of a via layer and/or a pattern of the wiring layer. Layout data D15 may have a format such as graphic design system information interchange (GDSII), and may have geometric information about cells and interconnections thereof. The semiconductor design tool may refer to the design rule D14 while routing pins of the cells. The layout data D15 may correspond to an arrangement and an output of routing. Operation S50 alone, or operations S30 and S50 comprehensively may be referred to as a method of designing an integrated circuit. In the specification, the layout data D15 may be referred to as output data.

In operation S70, an operation of fabricating a mask may be performed. For example, in photolithography, an optical probability correction (OPC) process for correcting a distortion phenomenon, such as refraction due to characteristics of light, may be applied to the layout data D15. Patterns on the mask may be defined to form patterns arranged on a plurality of layers based on data, to which the OPC has been applied, and at least one mask (or a photomask) for forming patterns of each of the plurality of layers may be manufactured. In some embodiments, the layout of the integrated circuit device IC may be limitedly modified in operation S70, and the limited modification on the layout of the integrated circuit device IC in operation S70 may include a post process for optimizing the structure of the integrated circuit device IC, which may be referred to as a design polishing process.

In operation S90, an operation of manufacturing the integrated circuit device IC may be performed. For example, the integrated circuit device IC may be manufactured by patterning the plurality of layers by using at least one mask fabricated in operation S70. A front-end-of-line (FEOL) process may include, for example, planarizing and cleaning of a wafer, forming a trench, forming a well, forming a gate electrode, and forming a source/drain region. By using the FEOL process, individual devices, for example, a transistor, a capacitor, a resistor, or the like may be formed on a substrate. In addition, a back-end-of-line (BEOL) process may include, for example, performing silicidation on a gate electrode and a source/drain region, adding a dielectric material, planarizing, forming a hole, adding a metal layer, forming a via, forming a passivation layer, etc. By using the BEOL process, individual devices, for example, a transistor, a capacitor, a resistor, or the like may be connected to one another. In some embodiments, a middle-of-line (MOL) process may be performed between the FEOL and BEOL processes, and contacts may be formed on individual devices. Next, the integrated circuit device IC may be packaged in a semiconductor package, and used as a component of various applications.

FIG. 13 is a detailed flowchart of operation S30 in FIG. 12.

Referring to FIG. 13, in operation S31, the second logic cell may be arranged in a portion of the logic cell region. The second logic cell may mean a cell having a relatively large cell height.

In operation S32, the first logic cell may be arranged in another portion of the logic cell region. The first logic cell may mean a cell having a relatively small cell height. In some embodiments, the cell height of the first logic cell may be a minimum value among the cell heights of the standard cells, and the cell height of the second logic cell may be an integer multiple of two or more times the cell height of the first logic cell. In some embodiments, the cell height of the second logic cell may be twice the cell height of the first logic cell.

In some embodiments, after operation S32 is performed, operation S31 may be performed.

In operation S33, the filler cell may be arranged in the filler cell region. In some embodiments, as illustrated in FIG. 2, in the filler cell region, the separation wall SWL and the gate cut structure PCT aligned with each other in the first horizontal direction (X direction) may be in contact with one another. In some embodiments, as illustrated in FIG. 5, the planar shape of the well may have a jog in which the well horizontal width is changed or shifted in the second horizontal direction (Y direction) in the filler cell region.

While the present inventive concept has been particularly shown and described with reference to example embodiments thereof, the present inventive concept is not limited to the example embodiments, and various changes and modifications may be made by those of ordinary skill in the art without departing from the spirit and scope of the present inventive concept.

What is claimed is:

1. An integrated circuit device comprising:
a first logic cell region and a second logic cell region adjacent to one another in a first horizontal direction;
a plurality of first logic cells arranged in portions of the first logic cell region and the second logic cell region, each of plurality of first logic cells having a first cell height; and
at least one second logic cell arranged in another portion of the second logic cell region and having a second cell height greater than the first cell height,
wherein both ends of the at least one second logic cell in a second horizontal direction substantially orthogonal to the first horizontal direction are aligned, in the first horizontal direction, with one end of both ends in the second horizontal direction of one first logic cell arranged in the first logic cell region among the plurality of first logic cells and another end of both ends in the second horizontal direction of another first logic cell arranged in the first logic cell region among the plurality of first logic cells.

2. The integrated circuit device of claim 1,
wherein each of the plurality of first logic cells comprises a first n-channel field effect transistor (FET) (NFET) and a first p-channel FET (PFET),
wherein the at least one second logic cell comprises a second NFET and a second PFET, and
wherein a channel width of each of the second NFET and the second PFET is greater than a channel width of each of the first NFET and the first PFET.

3. The integrated circuit device of claim 2, further comprising:
a first source/drain region included in each of the plurality of first logic cells;
a second source/drain region included in the at least one second logic cell;
a plurality of backside power rails extending in the first horizontal direction;
a plurality of backside power vias connected to at least one of the plurality of backside power rails; and
a plurality of backside via contacts configured to connect the first source/drain region and the second source/drain region to the plurality of backside power vias,
wherein one backside power via among the plurality of backside power vias is connected to a backside via contact connected to the second source/drain region among the plurality of backside via contacts, and the one backside power via is connected to two backside power rails among the plurality of backside power rails.

4. The integrated circuit device of claim 3, wherein one of two backside power rails among the plurality of backside power rails connected to the one backside power via extends from the second logic cell region into the first logic cell region.

5. The integrated circuit device of claim 4, wherein another of two backside power rails among the plurality of backside power rails connected to the one backside power via does not extend from the second logic cell region into the first logic cell region.

6. The integrated circuit device of claim 2, further comprising:
a P well in which the first NFET and the second NFET are arranged; and
an N well in which the first PFET and the second PFET are arranged,
wherein the P well and the N well respectively arranged in the one first logic cell and the another first logic cell among the plurality of first logic cells have planar shapes having a jog in which a well horizontal width is changed or shifted in the second horizontal direction and extend into the second logic cell region.

7. The integrated circuit device of claim 2, further comprising:
a separation structure arranged between the first logic cells adjacent to each other in the second horizontal direction, among the plurality of first logic cells.

8. The integrated circuit device of claim 7,
wherein each of the first NFET and the first PFET comprises a first nanosheet stacked structure including nanosheets sequentially apart from one another in a vertical direction, and
wherein the separation structure is in contact with the nanosheets included in the first nanosheet stacked structure.

9. The integrated circuit device of claim 7,
wherein each of the first NFET and the first PFET comprises a first nanosheet stacked structure including nanosheets sequentially apart from one another in a vertical direction, and
wherein the separation structure is apart from the nanosheets included in the first nanosheet stacked structure.

10. The integrated circuit device of claim 2, further comprising
a gate cut structure arranged between each of the first logic cells arranged in the second logic cell region among the plurality of first logic cells and the at least one second logic cell on both sides in the second horizontal direction of the at least one second logic cell,
wherein each of the second NFET and the second PFET comprises a second nanosheet stacked structure including nanosheets sequentially apart from one another in a vertical direction, and
wherein the gate cut structure is apart from the nanosheets included in the second nanosheet stacked structure.

11. An integrated circuit device comprising: a first logic cell region and a second logic cell region adjacent to one another in a first horizontal direction;
a plurality of first logic cells arranged in portions of the first logic cell region and the second logic cell region, each of the plurality of first logic cells having a first cell height; and
at least one second logic cell arranged in another portion of the second logic cell region and having a second cell height greater than the first cell height,
wherein the first logic cells arranged in the first logic cell region among the plurality of first logic cells are arranged in a second horizontal direction substantially orthogonal to the first horizontal direction,
wherein the first logic cells arranged in the second logic cell region among the plurality of first logic cells are arranged on both sides of the at least one second logic cell in the second horizontal direction,
wherein each of the plurality of first logic cells comprises a first n-channel field effect transistor (FET) (NFET) and a first p-channel FET (PFET),
wherein the at least one second logic cell comprises a second NFET and a second PFET, and
wherein a channel width of each of the second NFET and the second PFET is greater than a channel width of each of the first NFET and the first PFET, and
wherein both ends of the at least one second logic cell in the second horizontal direction are aligned, in the first horizontal direction, with one end of both ends in the second horizontal direction of one first logic cell arranged in the first logic cell region among the plurality of first logic cells and another end of both ends in the second horizontal direction of another first logic cell arranged in the first logic cell region among the plurality of first logic cells.

12. The integrated circuit device of claim 11,
further comprising a separation wall arranged between the first logic cells adjacent to one another in the second horizontal direction among the plurality of first logic cells,
wherein each of the first NFET and the first PFET comprises a first nanosheet stacked structure including nanosheets sequentially apart from one another in a vertical direction, and
wherein the separation wall is in contact with the nanosheets included in the first nanosheet stacked structure.

13. The integrated circuit device of claim 12,
further comprising a gate cut structure arranged between each of the first logic cells arranged in the second logic cell region among the plurality of first logic cells and the at least one second logic cell on both sides in the second horizontal direction of the at least one second logic cell,
wherein each of the second NFET and the second PFET comprises a second nanosheet stacked structure including nanosheets sequentially apart from one another in the vertical direction, and
wherein the gate cut structure is apart from the nanosheets included in the second nanosheet stacked structure.

14. The integrated circuit device of claim 13,
wherein the at least one second logic cell is aligned in the first horizontal direction with two first logic cells of the first logic cells arranged in the first logic cell region among the plurality of first logic cells, and
wherein the separation wall arranged between the two first logic cells and other first logic cell adjacent to the two first logic cells in the second horizontal direction is aligned with the gate cut structure in the first horizontal direction.

15. The integrated circuit device of claim 14,
further comprising a filler cell region arranged between the first logic cell region and the second logic cell region,
wherein the separation wall and the gate cut structure aligned with one another in the first horizontal direction extend into the filler cell region and are in contact with one another.

16. The integrated circuit device of claim 13, further comprising:
a first source/drain region included in each of the plurality of first logic cells and connected to the nanosheets included in the first nanosheet stacked structure;
a second source/drain region included in the at least one second logic cell and connected to the nanosheets included in the second nanosheet stacked structure;
a plurality of backside power rails extending in the first horizontal direction;
a plurality of backside power vias connected to at least one of the plurality of backside power rails; and
a plurality of backside via contacts configured to connect the first source/drain region and the second source/drain region to the plurality of backside power vias.

17. The integrated circuit device of claim 16,
wherein one backside power via among the plurality of backside power vias is connected to a backside via contact connected to the first source/drain region among the plurality of backside via contacts, and the one backside power via is connected to one backside power rail among the plurality of backside power rails, and
wherein another backside power via among the plurality of backside power vias is connected to a backside via contact connected to the second source/drain region among the plurality of backside via contacts, and the another backside power via is connected to two backside power rails among the plurality of backside power rails.

18. An integrated circuit device comprising: a first logic cell region and a second logic cell region adjacent to one another in a first horizontal direction;
a plurality of gate electrodes configured to extend in the first logic cell region and the second logic cell region in a second horizontal direction substantially orthogonal to the first horizontal direction;
a plurality of first logic cells arranged in portions of the first logic cell region and the second logic cell region, each of the plurality of first logic cells having a first cell height in the second horizontal direction; and
at least one second logic cell arranged in another portion of the second logic cell region and having a second cell height greater than the first cell height in the second horizontal direction,
wherein the first logic cells arranged in the first logic cell region among the plurality of first logic cells are arranged in the second horizontal direction,
wherein the first logic cells arranged in the second logic cell region among the plurality of first logic cells are arranged on both sides of the at least one second logic cell in the second horizontal direction,
wherein each of the plurality of first logic cells comprises a first nanosheet stacked structure including nanosheets arranged in portions overlapping any one of the plurality of gate electrodes in a vertical direction, sequentially apart from one another in the vertical direction, and having a first channel width, and a first source/drain region connected to the nanosheets included in the first nanosheet stacked structure,
wherein the at least one second logic cell comprises a second nanosheet stacked structure including nanosheets arranged in portions overlapping any one of the plurality of gate electrodes in the vertical direction, sequentially apart from one another in the vertical direction, and having a second channel width greater than the first channel width, and a second source/drain region connected to the nanosheets included in the second nanosheet stacked structure, and
wherein one end of both ends in the second horizontal direction of the at least one second logic cell is aligned in the first horizontal direction with one end of both ends in the second horizontal direction of one first logic cell arranged in the first logic cell region among the plurality of first logic cells, and another end of the both ends in the second horizontal direction of the at least one second logic cell is aligned in the first horizontal direction with the other end of the both ends in the second horizontal direction of another first logic cell arranged in the first logic cell region among the plurality of first logic cells.

19. The integrated circuit device of claim 18, further comprising:
a plurality of backside power rails extending in the first horizontal direction;
a plurality of backside power vias connected to at least one of the plurality of backside power rails; and
a plurality of backside via contacts configured to connect the first source/drain region and the second source/drain region to the plurality of backside power vias,
wherein one backside power via among the plurality of backside power vias is connected to a backside via contact connected to the first source/drain region among the plurality of backside via contacts, and the one backside power via is connected to one backside power rail among the plurality of backside power rails, and
wherein another backside power via among the plurality of backside power vias is connected to a backside via contact connected to the second source/drain region among the plurality of backside via contacts, and the another backside power via is connected to two backside power rails among the plurality of backside power rails.

20. The integrated circuit device of claim 18, wherein the second cell height is twice the first cell height.
